(19) United States
(12) Patent Application Publication
(10) Pub. No.: US 2025/0095752 A1
(43) Pub. Date: Mar. 20, 2025

(54) SEMICONDUCTOR MEMORY DEVICE AND MEMORY SYSTEM

(71) Applicant: Kioxia Corporation, Tokyo (JP)

(72) Inventors: Yoshikazu TAKEYAMA, Fujisawa Kanagawa (JP); Keisuke TAKAHASHI, Yokohama Kanagawa (JP)

(21) Appl. No.: 18/821,670

(22) Filed: Aug. 30, 2024

(30) Foreign Application Priority Data
Sep. 20, 2023 (JP) 2023-152249

(51) Int. Cl. G11C 16/30; G06N 3/0455; G11C 16/04; G11C 16/10; G11C 16/14; G11C 16/26

(52) U.S. Cl. CPC G11C 16/30; G06N 3/0455; G11C 16/0483; G11C 16/10; G11C 16/14; G11C 16/26

(57) ABSTRACT

A semiconductor memory device includes a memory cell array, a control circuit, and a voltage generation circuit. The control circuit is configured to perform a first operation to access the memory cell array and then a second operation to access the memory cell array. The voltage generation circuit is configured to generate a first operation voltage, which is supplied from an output terminal of the voltage generation circuit to the memory cell array during the first operation, and a second operation voltage, which is supplied from the output terminal to the memory cell array during the second operation. The control circuit is configured to control the voltage generation circuit to maintain a voltage output from the output terminal to be at the first operation voltage after the first operation until the second operation voltage starts to be supplied to the memory cell array for the second operation.

### CROSS-REFERENCE TO RELATED APPLICATION

This application is based upon and claims the benefit of priority from Japanese Patent Application No. 2023-152249, filed Sep. 20, 2023, the entire contents of which are incorporated herein by reference.

### FIELD

Embodiments described herein relate generally to a semiconductor memory device and a memory system.

### BACKGROUND

As semiconductor memory devices, for example, NAND flash memories in which memory cells are arranged 2-dimensionally or 3-dimensionally are known. Memory systems that include NAND flash memories and memory controllers that control the NAND flash memories are known.

### BRIEF DESCRIPTION OF THE DRAWINGS

FIG. 1 is a block diagram illustrating a configuration of a memory system according to a first embodiment.

FIG. 2 is a block diagram illustrating a configuration of a semiconductor memory device according to the first embodiment.

FIG. 3 is a circuit diagram illustrating a block in a memory cell array according to the first embodiment.

FIG. 4 is a diagram illustrating a part of a planar layout of the memory cell array according to the first embodiment.

FIG. 5 is a diagram illustrating a cross section along the line V-V of FIG. 4.

FIG. 6 is a diagram illustrating a cross section along the line VI-VI of FIG. 5.

FIG. 7 is a diagram illustrating an example of a configuration of a voltage generation circuit according to the first embodiment.

FIG. 8 is a diagram illustrating a relation between data and a threshold voltage distribution taken by memory cell transistors according to the first embodiment.

FIG. 9 is a diagram illustrating an internal voltage in a consecutive operation according to the first embodiment.

FIG. 10 is a diagram illustrating an internal voltage in a consecutive operation according to a comparative example.

FIG. 11 is a diagram illustrating a first example of a command sequence in a write operation according to the first embodiment.

FIG. 12 is a diagram illustrating a second example of the command sequence in the write operation according to the first embodiment.

FIG. 13 is a diagram illustrating an internal voltage and a write voltage in the write operation according to the first embodiment.

FIG. 14 is a diagram illustrating an internal voltage and a write voltage in the write operation according to a comparative example.

FIG. 15 is a diagram illustrating a first example of a command sequence in a read operation according to the first embodiment.

FIG. 16 is a diagram illustrating a second example of the command sequence in the read operation according to the first embodiment.

FIG. 17 is a diagram illustrating an internal voltage and a read voltage in the read operation according to the first embodiment.

FIG. 18 is a diagram illustrating an internal voltage and a read voltage in a read operation according to a comparative example.

FIG. 19 is a diagram illustrating a first example of a command sequence in an erasing operation according to the first embodiment.

FIG. 20 is a diagram illustrating a second example of the command sequence in the erasing operation according to the first embodiment.

FIG. 21 is a diagram illustrating an internal voltage and an erasing voltage in the erasing operation according to the first embodiment.

FIG. 22 is a diagram illustrating an internal voltage and an erasing voltage in the erasing operation according to a comparative example.

FIG. 23 is a diagram illustrating a first example of a command sequence in an erasing operation, a write operation, and a read operation according to a second embodiment.

FIG. 24 is a diagram illustrating a second example of the command sequence in the erasing operation, the write operation, and the read operation according to the second embodiment.

FIG. 25 is a diagram illustrating an internal voltage, an erasing voltage, a write voltage, and a read voltage in the erasing operation, the write operation, and the read operation according to the second embodiment.

### DETAILED DESCRIPTION

Embodiments provide a semiconductor memory device and a memory system capable of shortening a time of each inter-operation in an operation to access a memory cell array, such as a write operation, a read operation, or an erasing operation.

In general, according to an embodiment, a semiconductor memory device includes a memory cell array, a control circuit, and a voltage generation circuit. The control circuit is configured to perform a first operation to access the memory cell array and then a second operation to access the memory cell array. The voltage generation circuit configured to generate a first operation voltage, which is supplied to from an output terminal of the voltage generation circuit to the memory cell array during the first operation, and a second operation voltage, which is supplied from the output terminal to the memory cell array during the second operation. The control circuit is configured to control the voltage generation circuit to maintain a voltage output from the output terminal to be at the first operation voltage after the first operation until the second operation voltage starts to be supplied to the memory cell array for the second operation.

In the following description, common reference numerals denote elements that have the same functions and configurations. The following embodiments are illustrative of devices or methods for embodying technical spirits according to the embodiments and do not specify materials, shapes, structures, dispositions, and the like of the elements.

Functional blocks can be implemented as any of hardware and computer software or a combination thereof. It is not necessary for functional blocks to be distinguished from each other as in the following examples. For example, some functions may be executed by different functional blocks from those illustrated. Further, the illustrated functional blocks may be further divided into finer functional sub-blocks.

Hereinafter, a memory system including a semiconductor memory device and a memory controller according to an embodiment will be described. As the semiconductor memory device, a 3-dimensionally stacked NAND flash memory in which memory cell transistors are stacked above a semiconductor substrate 3-dimensionally is exemplified.

For example, in the memory system, operation commands to write, read, and erase data are transmitted from the memory controller to the semiconductor memory device when the semiconductor memory device is caused to write, read, and erase the data.

When the operation command is received, the semiconductor memory device uses a voltage generation circuit (or a boosting circuit) to generate an operation voltage necessary for an operation instructed with the operation command. Hereinafter, a voltage generated by the voltage generation circuit is referred to as an internal voltage and a process in which the voltage generation circuit boosts an initial voltage and generates the internal voltage is referred to as a boosting process.

Next, an operation in response to the operation command in the semiconductor memory device is executed using the internal voltage. When the operation using the internal voltage ends, a process in which the voltage generation circuit drops the internal voltage to an initial voltage (hereinafter referred to as a recovery) is executed.

Thereafter, when a subsequent operation command is received, the semiconductor memory device uses the voltage generation circuit again and generates an internal voltage necessary for an operation instructed with the operation command. That is, a boosting process in which the voltage generation circuit boosts the initial voltage again and generates the internal voltage is executed.

In this way, a recovery and a boosting process of the internal voltage are repeated between a previous operation and a subsequent operation. Therefore, a time from reception of an operation command by the semiconductor memory device to start of an operation and a time from end of the previous operation to start of the subsequent operation may become long. When the time from the previous operation to the subsequent operation is short, power consumption may be larger in repetition of the recovery and the boosting process of the internal voltage between respective operations than holding of a voltage level (or a voltage value) of the internal voltage between respective operations.

In embodiments to be described below, it is possible to achieve a reduction in a time between a previous operation and a subsequent operation and a reduction of power consumption between the previous operation and the subsequent operation by not executing a recovery and a boosting process for an internal voltage after end of the previous operation between the previous operation and the subsequent operation, that is, by holding a voltage level of an internal voltage between the previous operation and the subsequent operation. Hereinafter, the holding of the voltage level of the internal voltage is also referred to as holding of the internal voltage.

### 1. First Embodiment

A memory system including a semiconductor memory device and a memory controller according to a first embodiment will be described.

### 1.1 Configuration of Memory System

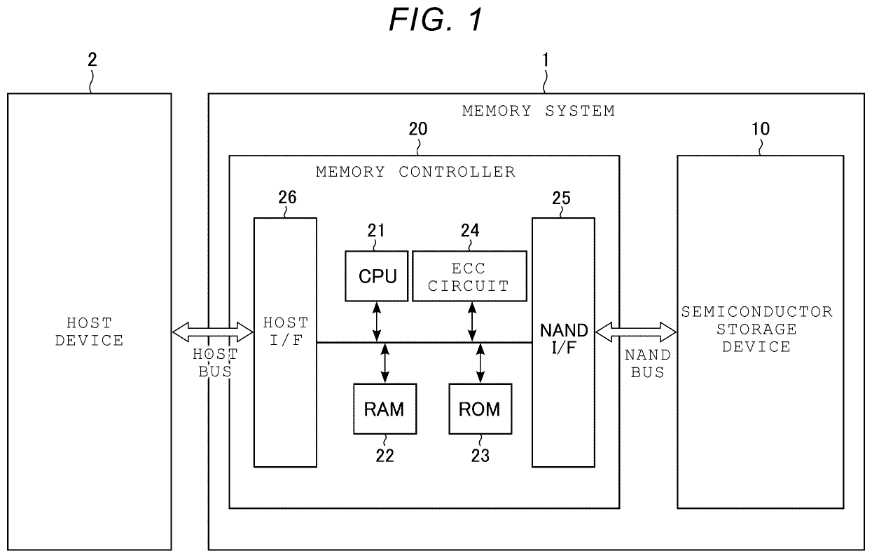

A configuration of the memory system according to the first embodiment will be described. FIG. 1 is a block diagram illustrating a configuration of the memory system according to the first embodiment. A memory system 1 is connected to an external host device 2 and executes various operations in response to commands from the host device 2. The memory system 1 includes a semiconductor memory device 10 and a memory controller 20.

The semiconductor memory device 10 includes, for example, a NAND flash memory and stores data in a nonvolatile manner. Details of the semiconductor memory device 10 will be described below.

The memory controller 20 is connected to the semiconductor memory device 10 via a NAND bus. The memory controller 20 controls the semiconductor memory device 10. The NAND bus is used to transmit and receive signals in accordance with a NAND interface. The memory controller 20 is connected to the host device 2 via a host bus. The memory controller 20 accesses the semiconductor memory device 10 in response to a command received from the host device 2.

For example, the semiconductor memory device 10 and the memory controller 20 may be combined to configure one semiconductor device. As an example, a memory card including an SD™ card, a solid state drive (SSD), or the like can be exemplified. The memory controller 20 may be, for example, a system-on-a-chip (SoC) or the like. The host device 2 is, for example, a digital camera, a personal computer, or the like. The host bus is, for example, a bus in accordance with an SD™ interface.

### 1.1.1 Memory Controller

A configuration of the memory controller 20 will be described with reference to FIG. 1. The memory controller 20 includes a central processing unit (CPU) (or a processor) 21, a random access memory (RAM) 22, a read only memory(ROM) 23, an error checking and correcting (ECC) circuit 24, a NAND interface circuit (NAND I/F) 25, and a host interface circuit (host I/F) 26.

The CPU 21 controls an operation of the entire memory controller 20. For example, when a write command is received from the host device 2, the CPU 21 issues a write command via the NAND interface circuit 25 in response to the received write command. When a read command and an erase command are received, the CPU 21 also issues a read command and an erase command to the NAND interface circuit 25 in response to the received read command and the received erase command.

The CPU 21 executes various processes of managing the semiconductor memory device 10 such as wear labeling. Operations of the memory controller 20 to be described below may be implemented by the CPU 21 executing software (or firmware) or may be implemented by hardware.

The RAM 22 is used as a work area of the CPU 21. The RAM 22 temporarily stores firmware, various management tables, data, and the like for managing the semiconductor memory device 10. The RAM 22 is, for example, a semiconductor memory such as a dynamic random access memory (DRAM) or a static random access memory (SRAM). The ROM 23 stores, for example, firmware that is executed by the CPU 21.

The ECC circuit 24 performs processes related to error detection and correction on write data written on the semiconductor memory device 10 and read data read from the semiconductor memory device 10.

The NAND interface circuit 25 is connected to the semiconductor memory device 10 via the NAND bus to communicate with the semiconductor memory device 10. The NAND interface circuit 25 transmits various signals, commands, and pieces of data based on commands received from the CPU 21 to the semiconductor memory device 10. The NAND interface circuit 25 receives various signals and data from the semiconductor memory device 10.

The host interface circuit 26 is connected to the host device 2 via the host bus to communicate with the host device 2. The host interface circuit 26 transmits each of a command and data received from the host device 2 to the CPU 21 and the RAM 22. The host interface circuit 26 outputs data in the RAM 22 to the host device 2 in response to a command from the CPU 21.

### 1.1.2 Semiconductor Memory Device

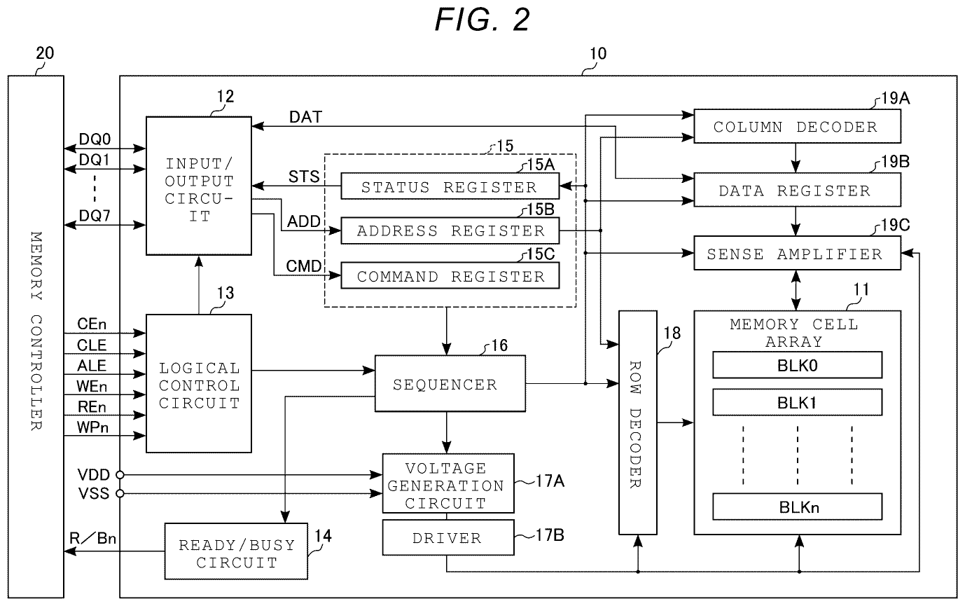

Next, a configuration of the semiconductor memory device 10 will be described. FIG. 2 is a block diagram illustrating a configuration of the semiconductor memory device 10 according to the first embodiment.

The semiconductor memory device 10 includes a memory cell array 11, an input/output circuit 12, a logical control circuit 13, a ready/busy circuit 14, a register group 15, a sequencer (or a control circuit) 16, a voltage generation circuit 17A, a driver 17B, a row decoder 18, a column decoder 19A, a data register 19B, and a sense amplifier 19C. The register group 15 includes a status register 15A, an address register 15B, and a command register 15C.

The memory cell array 11 includes one block or a plurality of blocks BLK0, BLK1, BLK2, . . . , and BLKn (where n is an integer of 0 or more). Each of the plurality of blocks BLK0 to BLKn includes a plurality of memory cell transistors (hereinafter referred to as memory cells) associated with rows and columns. The memory cell transistors are nonvolatile memory cells capable of executing electric erasing and programming. The memory cell array 11 includes a plurality of word lines, a plurality of bit lines, and a source line for applying voltages to the memory cell transistors. A specific configuration of the block BLKn will be described below.

The input/output circuit 12 and the logical control circuit 13 are connected to the memory controller 20 via an input/output terminal (or the NAND bus).

The input/output circuit 12 transmits and receives input/output signals (I/O signals) DQ (for example, DQ0, DQ1, DQ2, . . . , and DQ7) to and from the memory controller 20 via the input/output terminal. The I/O signals DQ are used to communication for commands, addresses, data, and the like.

The logical control circuit 13 receives control signals from the memory controller 20 via the input/output terminal. The control signals include, for example, a chip enable signal CEn, a command latch enable signal CLE, an address latch enable signal ALE, a write enable signal WEn, a read enable signal REn, and a write protection signal WPn. “n” suffixed to a signal name indicates that a signal is an active-low signal.

The chip enable signal CEn is asserted when one semiconductor memory device 10 is selected among the plurality of semiconductor memory devices 10. The command latch enable signal CLE enables a command transmitted as a signal DQ to be latched in the command register 15C. The address latch enable signal ALE enables an address transmitted as a signal DQ to be latched in the address register 15B. The write enable signal WEn enables data transmitted as a signal DQ to be stored in the data register 19B. The read enable signal REn enables data read from the memory cell array 11 to be output as a signal DQ. The write protection signal WPn is asserted when a write operation and an erasing operation on the semiconductor memory device 10 are prohibited.

The ready/busy circuit 14 generates a ready/busy signal R/Bn in accordance with control by the sequencer 16. The ready/busy signal R/Bn indicates whether the semiconductor memory device 10 is in a ready state or a busy state. The ready state indicates that the semiconductor memory device 10 is in a state in which a command from the memory controller 20 can be received. The busy state indicates that the semiconductor memory device 10 is in a state in which a command from the memory controller 20 cannot be received. The memory controller receives the ready/busy signal R/Bn from the semiconductor memory device 10, and can ascertain whether the semiconductor memory device 10 is in the ready state or the busy state.

The status register 15A stores status information STS necessary for an operation of the semiconductor memory device 10. The status register 15A transmits the status information STS to the input/output circuit 12 in response to an instruction of the sequencer 16.

The address register 15B stores an address ADD transmitted from the input/output circuit 12. The address ADD includes a row address and a column address. The row address includes, for example, a block address for designating a block BLKn of an operation target and a page address for designating a word line WL (for example, a page) of the operation target in the designated block.

The command register 15C stores a command CMD transmitted from the input/output circuit 12. The command CMD includes, for example, a write command for instructing the sequencer 16 to execute a write operation, a read command for instructing the sequencer 16 to execute a read operation, and an erase command for instructing the sequencer 16 to execute an erasing operation.

For the status register 15A, the address register 15B, and the command register 15C, for example, a static random access memory (SRAM) is used.

The sequencer 16 receives a command from the command register 15C and comprehensively controls the semiconductor memory device 10 in accordance with a sequence based on the command.

The sequencer 16 controls the voltage generation circuit 17A, the driver 17B, the row decoder 18, the column decoder 19A, the data register 19B, the sense amplifier 19C, and the like and executes a write operation, a read operation, and an erasing operation. Specifically, the sequencer 16 controls the voltage generation circuit 17A, the driver 17B, the row decoder 18, and the sense amplifier 19C based on a write command received from the command register 15C and writes data in a plurality of memory cell transistors designated with the address ADD. The sequencer 16 controls the voltage generation circuit 17A, the driver 17B, the row decoder 18, the column decoder 19A, and the sense amplifier 19C based on a read command received from the command register 15C and reads data from a plurality of memory cell transistors designated with the address ADD. The sequencer 16 controls the voltage generation circuit 17A, the driver 17B, the row decoder 18, the column decoder 19A, and the sense amplifier 19C based on an erase command received from the command register 15C and erases data stored in a block designated with the address ADD.

A function of the sequencer 16 described in the present disclosure may be implemented by the sequencer 16 executing software (or firmware) or may be implemented by hardware (or a dedicated circuit).

The voltage generation circuit 17A receives a power voltage VDD and a ground voltage VSS via a power terminal from the outside of the semiconductor memory device 10. The power voltage VDD is an external voltage supplied from the outside of the semiconductor memory device 10. The ground voltage VSS is an external voltage supplied from the outside of the semiconductor memory device 10 and is, for example, 0 V.

The voltage generation circuit 17A generates a plurality of operation voltages necessary for a write operation, a read operation, an erasing operation using the power voltage VDD. The voltage generation circuit 17A supplies the generated voltages to the memory cell array 11, the row decoder 18, the sense amplifier 19C, and the like via the driver 17B. A specific configuration of the voltage generation circuit 17A will be described below.

The driver 17B receives the plurality of voltages output from the voltage generation circuit 17A. The driver 17B supplies a plurality of voltages selected in accordance with a read operation, a write operation, and an erasing operation from the plurality of voltages supplied from the voltage generation circuit 17A to the row decoder 18, the memory cell array 11, and the sense amplifier 19C via the plurality of signal lines. The driver 17B supplies internal voltages supplied from the voltage generation circuit 17A as a write voltage VPGM and a write pass voltage VPASS to a word line, for example, during a write operation. The driver 17B supplies internal voltages supplied from the voltage generation circuit 17A as a read voltage VCGRV and a read pass voltage VREAD to a word line, for example, during a read operation. Further, the driver 17B supplies an internal voltage supplied from the voltage generation circuit 17A as an erasing voltage VERA to a source line, for example, during an erasing operation.

The row decoder 18 receives a row address from the address register 15B and decodes the row address. The row decoder 18 selects one block from a plurality of blocks based on a decoding result of the row address and selects a word line WL in the selected block BLKn. Further, the row decoder 18 transmits the plurality of voltages supplied from the driver 17B to the selected block BLKn.

The column decoder 19A receives a column address from the address register 15B and decodes the column address. The column decoder 19A selects a latch circuit in the data register 19B based on a decoding result of the column address.

The data register 19B includes a plurality of latch circuits. The latch circuits in the data register 19B temporarily store write data and read data during a write operation and a read operation, respectively.

The sense amplifier 19C senses and amplifies data read from a memory cell transistor to a bit line during a data read operation. Further, the sense amplifier 19C temporarily stores read data that is read from the memory cell transistor and transmits the stored read data to the data register 19B. The sense amplifier 19C temporarily stores write data transmitted from the input/output circuit 12 via the data register 19B during a data write operation. Further, the sense amplifier 19C transmits the write data to the bit line.

### 1.1.2.1 Memory Cell Array

Next, a circuit configuration and structure of the memory cell array 11 in the semiconductor memory device 10 according to the first embodiment will be described.

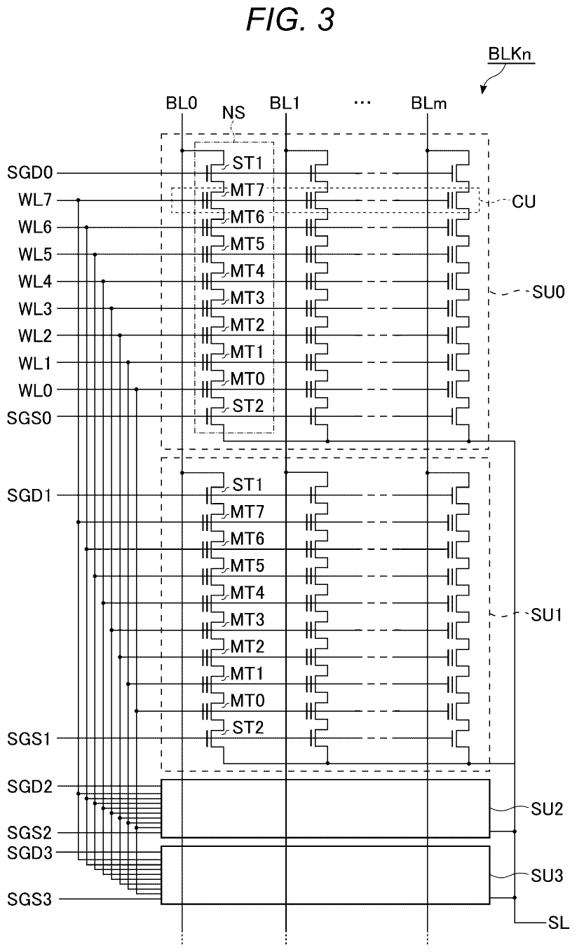

As described above, the memory cell array 11 includes a plurality of blocks BLK0 to BLKn. Hereinafter, a circuit configuration of the block BLKn will be described. FIG. 3 is a circuit diagram illustrating the block BLKn in the memory cell array 11.

The block BLKn includes, for example, four string units SU0, SU1, SU2, and SU3. Hereinafter, when a string unit SU is referred to, the string units SU is assumed to indicate each of the string units SU0 to SU3.

The string unit SU includes a plurality of NAND strings NS respectively associated with bit lines BL0, BL1, BL2, . . . , and BLm (where m is an integer of 0 or more). Each NAND string NS includes, for example, memory cell transistors MT0, MT1, MT2, . . . , and MT7 and select transistors ST1 and ST2. Hereinafter, when a bit line BL is referred to, the bit line BL indicates each of the bit lines BL0 to BLm. When a memory cell transistor MT is referred to, the memory cell transistor MT indicates each of the memory cell transistors MT0 to MT7.

The memory cell transistor MT includes a control gate and a charge storage layer and stores data in a nonvolatile manner. Each of the select transistors ST1 and ST2 is used to select the string unit SU during various operations.

In each NAND string NS, the memory cell transistors MT0 to MT7 are connected in series. The select transistor ST1 is connected between one end of each of the memory cell transistors MT0 to MT7 connected in series and associated bit line. A drain of the select transistor ST2 is connected to the other end of each of the memory cell transistors MT0 to MT7 connected in series. Each of a source line SL and a well line CPWELL (not illustrated) is connected to a source of the select transistor ST2.

In the same block BLKn, a gate of each of the plurality of select transistors ST1 included in the string units SU0 to SU3 is commonly connected to the select gate lines SGD0 to SGD3. A control gate of each of the plurality of memory cell transistors MT0 to MT7 is commonly connected to each of word lines WL0 to WL7. A gate of each of the plurality of select transistors ST2 is commonly connected to each of select gate lines SGS0 to SGS3. Hereinafter, when a select gate line SGD is referred to, the select gate line SGD indicates each of the select gate lines SGD0 to SGD3. When a select gate line SGS is referred to, the select gate line SGS indicates each of the select gate lines SGS0 to SGS3.

The bit lines BL0 to BLm are shared between the plurality of blocks BLK0 to BLKn. The same bit lines BL are connected to a NAND string NS corresponding to the same column address. Each of the word lines WL0 to WL7 is provided for each block BLKn. The source line SL is shared between, for example, the plurality of blocks BLK0 to BLKn. That is, the source line SL is connected to sources of the plurality of select transistors ST2 included in the block BLKn.

The block BLKn is, for example, erasing units of data. That is, data of the plurality of blocks BLK0 to BLKn is sequentially erased for each block BLKn. Data stored in the memory cell transistor MT included in the block BLKn is erased collectively.

A set including the plurality of memory cell transistors MT connected to the common word line WL in one string unit SU is referred to as, for example, a cell unit CU. For example, a storage capacitance of the cell unit CU including the memory cell transistor MT that stores 1-bit data is defined as, “1-page data”. The cell unit CU can have a storage capacitance of 2-page data or more in accordance with the number of bits of data stored by the memory cell transistor MT.

The circuit configuration of the memory cell array 11 described above is merely exemplary and an embodiment is not limited thereto. For example, the number of string units SU included in the block BLKn can be designed to any number. The number of memory cell transistors MT and the number of select transistors ST1 and ST2 included in each NAND string NS can be designed to any number.

Net, an example of a structure of the memory cell array 11 in the semiconductor memory device 10 according to the first embodiment will be described. Hereinafter, a 3-dimensionally stacked NAND flash memory in which memory cell transistors are stacked above a semiconductor substrate 3-dimensionally will be exemplified as the memory cell array 11.

In drawings referred to below, the X direction corresponds to an extension direction of the word line WL and the Y direction corresponds to an extension direction of the bit line BL. Further, the Z direction corresponds to a vertical direction to the surface of the semiconductor substrate on which the semiconductor memory device 10 is formed, in other words, corresponds to a direction in which the plurality of word lines WL are stacked on the surface of the semiconductor substrate. A hatching given in a plan view is not necessarily associated with a material or characteristic of an element to which a hatching is given. In the present disclosure, elements such as wirings, contacts, and insulating layers are appropriately omitted to facilitate understanding of the drawings.

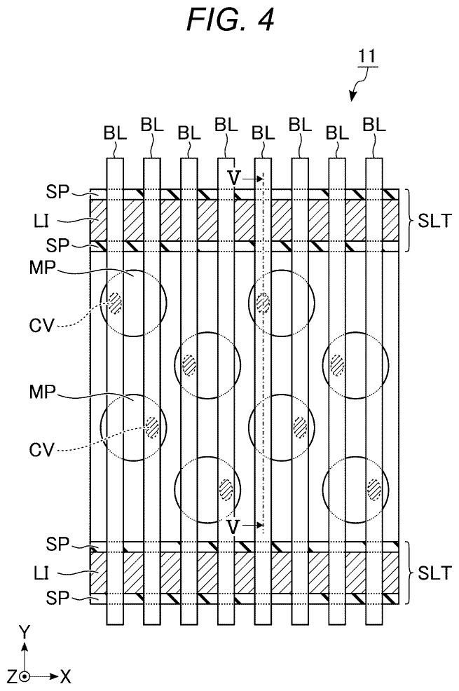

First, an example of a planar layout of the memory cell array 11 will be described. FIG. 4 is a diagram illustrating a part of a planar layout of the memory cell array 11 according to the first embodiment.

The memory cell array 11 includes, for example, a plurality of slits SLT, a plurality of memory pillars MP, a plurality of contacts CV, and a plurality of bit lines BL.

The plurality of slits SLT are arranged in the Y direction. At least a part of each slit SLT extends in the X direction. The slits SLT are provided in the same wiring layer and segment conductive layers adjacent to each other via the slits SLT. Specifically, the slits SLT respectively segment, for example, a plurality of wiring layers corresponding to the word lines WL0 to WL7 and the select gate lines SGD and SGS.

Each slit SLT includes, for example, a spacer SP and a contact LI. In each slit SLT, at least a part of the contact LI extends in the X direction. The spacer SP is provided on a side surface of the contact LI. The spacers SP separate and insulate the contacts LI and a plurality of wiring layers adjacent to the slits SLT from each other. The contact LI is used as the source line SL. The contact LI may be formed of a semiconductor or a metal. The spacer SP is an insulating layer and includes, for example, a silicon oxide (SiO₂).

Each memory pillar MP functions as, for example, one NAND string NS. The plurality of memory pillars MP are disposed, for example, in a zigzag form of four columns in a region between two slits SLT adjacent to each other. An embodiment is not limited thereto, and the number and disposition of memory pillars MP between two slits adjacent to each other can be appropriately changed.

At least one bit line BL is disposed to overlap each memory pillar MP. The plurality of bit lines BL are arranged in the X direction. At least a part of each bit line BL extends in the Y direction. Out of the plurality of bit lines BL overlapping the memory pillar MP, one bit line BL and the memory pillar MP are electrically connected to each other via the contact CV.

A planar layout of the memory cell array 11 described above is repeatedly disposed in the Y direction. Each region partitioned by the slits SLT corresponds to one string unit SU. That is, a set including string units SU0 to SU3 extending in the X direction are arranged in the Y direction. One contact CV is connected to one bit line BL, for example, in a space partitioned by the slits SLT.

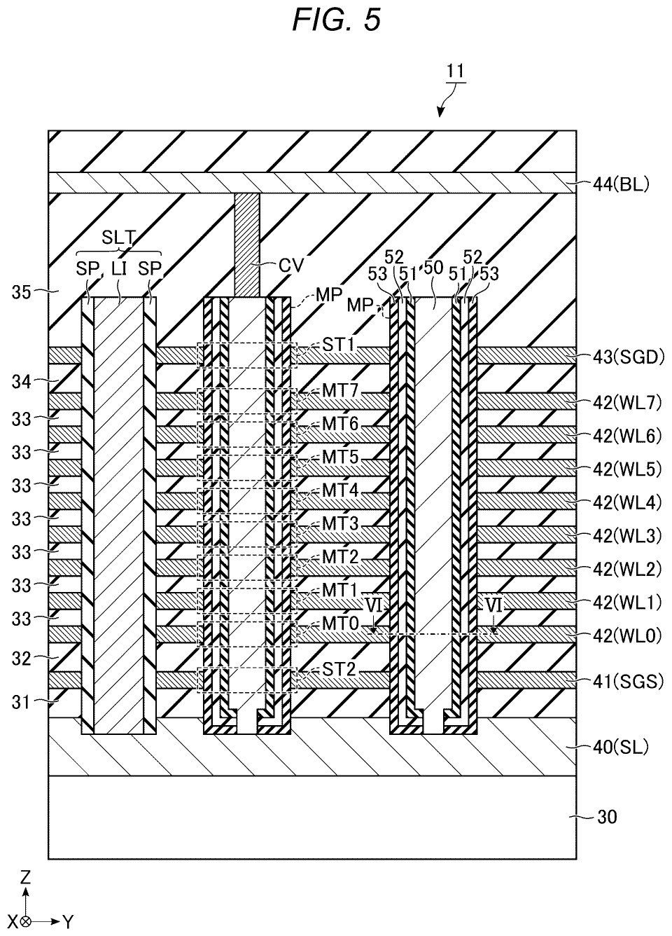

Next, an example of a cross-sectional structure of the memory cell array 11 will be described. FIG. 5 is a diagram illustrating a cross section along the line V-V of FIG. 4 and illustrating a cross section along the Y direction, including the memory pillar MP and the slit SLT.

The memory cell array 11 includes a semiconductor substrate 30, insulating layers 31 to 35, conductive layers 40 to 44, the memory pillars MP, the contacts CV, and the slits SLT.

The conductive layer 40 is provided above the semiconductor substrate 30. The conductive layer 40 is formed, for example, in a plate shape spread along an XY plane and is used as the source line SL. The conductive layer 40 contains, for example, phosphorus-doped polysilicon.

The insulating layer 31 is provided above the conductive layer 40. The conductive layer 41 is provided above the insulating layer 31. The conductive layer 41 is formed, for example, in a plate shape spread along an XY plane and is used as the select gate line SGS. The conductive layer 41 contains, for example, phosphorus-doped polysilicon. The select gate line SGS may include the plurality of conductive layers 41. When the select gate line SGS includes the plurality of conductive layers 41, the plurality of conductive layers 41 may include different conductors.

The insulating layer 32 is provided above the conductive layer 41. The conductive layer 42 and the insulating layer 33 are stacked alternately above the insulating layer 32. Each of the plurality of conductive layers 42 is formed, for example, in a plate shape spread along an XY plane. The plurality of conductive layers 42 are used as word lines WL0 to WL7 in order from the conductive layer 40 side. The conductive layer 42 contains, for example, tungsten.

The insulating layer 34 is provided above the uppermost conductive layer 42. The conductive layer 43 is provided above the insulating layer 34. The conductive layer 43 is formed, for example, in a plate shape spread along an XY plane and is used as the select gate line SGD. The select gate line SGD may include the plurality of conductive layers 43. The conductive layer 43 contains, for example, tungsten.

The insulating layer 35 is provided above the conductive layer 43. The conductive layer 44 is provided above the insulating layer 35. The conductive layer 44 is formed, for example, in a line shape extending in the Y direction and is used as the bit line BL. In a region (not illustrated), the plurality of conductive layers 44 are arranged in the X direction. The conductive layer 44 contains, for example, copper.

Each memory pillar MP extends in the Z direction. Each memory pillar MP penetrates through the insulating layers 31 to 34 and the conductive layers 41 to 43. The conductive layer 40 is in contact with a lower portion of the memory pillar MP. An upper portion of the memory pillar MP reaches the insulating layer 35.

Each memory pillar MP includes, for example, a semiconductor layer 50, a tunnel insulating layer (also referred to as a tunnel insulating film) 51, a charge storage layer (for example, an insulating layer) 52, and a block insulating layer 53.

The semiconductor layer 50 extends in the Z direction. For example, a lower end of the semiconductor layer 50 is in contact with the conductive layer 40. An upper end of the semiconductor layer 50 is included in a layer that includes the insulating layer 35. The tunnel insulating layer 51 is disposed on a side surface of the semiconductor layer 50. The charge storage layer 52 is disposed on a side surface of the tunnel insulating layer 51. The block insulating layer 53 is disposed on a side surface of the charge storage layer 52.

A portion in which the memory pillar MP intersects the conductive layer 41 (that is, the select gate line SGS) functions as the select transistor ST2. Portions in which the memory pillar MP intersects the plurality of conductive layers 42 (that is, the word line WL) function as the memory cell transistors MT0 to MT7. A portion in which the memory pillar MP intersects the conductive layer 43 (that is, the select gate line SGD) functions as the select transistor ST1. The semiconductor layer 50 functions as a channel layer of each of the memory cell transistors MT0 to MT7 and the select transistors ST1 and ST2. Inside the semiconductor layer 50, a current path of the NAND string NS is formed. The charge storage layer 52 functions as a layer that stores charges of the memory cell transistors MT.

The columnar contact CV is provided above the semiconductor layer 50 of each memory pillar MP. In the illustrated region, the contact CV corresponding to one memory pillar MP between two memory pillars MP is illustrated. The contact CV in the region (not illustrated) is connected to the memory pillar MP to which the contact CV is not connected in the region. Above the contact CV, one conductive layer 44 (that is, the bit line BL) is in contact.

The slit SLT includes, for example, the spacer SP and the contact LI. The slit SLT is at least partially formed in a plate shape spread along an XZ plane and segments the insulating layers 31 to 34 and the conductive layers 41 to 43. A lower end of the slit SLT is in contact with, for example, the conductive layer 40. An upper end of the slit SLT is included in a layer that includes the insulating layer 35. In the slit SLT, at least a part of the contact LI extends in the X direction. The spacer SP is provided on a side surface of the contact LI. The spacer SP separates and insulates the contact LI and the plurality of conductive layers 41 to 43 from each other.

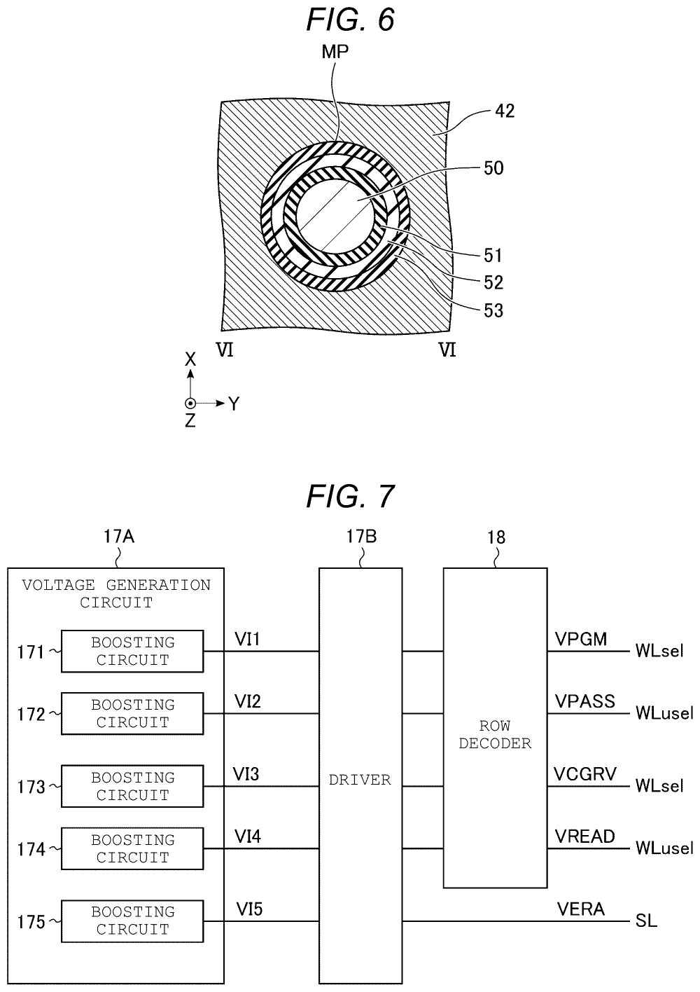

Next, a cross-sectional structure of the memory pillar MP in the memory cell array 11 will be described. FIG. 6 is a diagram illustrating a cross section along the line VI-VI of FIG. 5 and illustrating a cross section of the memory pillar MP in a layer that is parallel to the surface of the semiconductor substrate 30 and includes the conductive layer 42.

The memory pillar MP includes, for example, the semiconductor layer 50, the tunnel insulating layer 51, the charge storage layer 52, and the block insulating layer 53, as described above. Specifically, the semiconductor layer 50 is provided, for example, in a middle portion of the memory pillar MP. The tunnel insulating layer 51 surrounds the side surface of the semiconductor layer 50. The charge storage layer 52 surrounds the side surface of the tunnel insulating layer 51. The block insulating layer 53 surrounds the side surface of the charge storage layer 52. The conductive layer 42 surrounds the side surface of the block insulating layer 53. The memory pillar MP may have a structure in which the core insulating layer is provided inside the semiconductor layer 50.

The tunnel insulating layer 51 functions as a potential barrier when charges are injected from the semiconductor layer 50 to the charge storage layer 52 or charges stored in the charge storage layer 52 are spread to the semiconductor layer 50. The tunnel insulating layer 51 contains, for example, a silicon oxide (SiO₂).

The charge storage layer 52 has a function of storing the charges injected from the semiconductor layer 50 in the memory cell transistors MT0 to MT7. The charge storage layer 52 contains, for example, a silicon nitride (SiN).

The block insulating layer 53 prevents the charges stored in the charge storage layer 52 from spreading to the conductive layer 42 (the word line WL). The block insulating layer 53 includes, for example, an aluminum oxide layer, a silicon oxide layer, and a silicon nitride layer.

### 1.1.2.2 Voltage Generation Circuit

Next, a configuration of the voltage generation circuit 17A in the semiconductor memory device 10 according to the first embodiment will be described.

As described above, the voltage generation circuit 17A generates a plurality of operation voltages (may be referred to as internal voltages) necessary for an operation to access the memory cell array 11, such as a write operation, a read operation, and an erasing operation using the power voltage VDD. FIG. 7 is a diagram illustrating an example of a configuration of the voltage generation circuit 17A.

The voltage generation circuit 17A includes boosting circuits 171, 172, 173, 174, and 175. The boosting circuits 171, 172, 173, 174, and 175 generate, for example, a plurality of internal voltages used for a write operation, a read operation, or an erasing operation.

The boosting circuit 171 generates and outputs an internal voltage VI1 used during a write operation via an output terminal of the voltage generation circuit 17A. The boosting circuit 172 generates and outputs an internal voltage VI2 used during the write operation via an output terminal of the voltage generation circuit 17A. In the write operation, the internal voltage VI1 output from the boosting circuit 171 is supplied as a write voltage VPGM to a word line (or a selected word line) WLsel of a writing target via the driver 17B and the row decoder 18. The internal voltage VI2 output from the boosting circuit 172 is supplied as a write pass voltage VPASS to a word line (or a non-selected word line) WLusel of a non-writing target via the driver 17B and the row decoder 18.

The boosting circuit 173 generates and outputs an internal voltage VI3 used during a read operation via an output terminal of the voltage generation circuit 17A. The boosting circuit 174 generates and outputs an internal voltage VI4 used during the read operation via an output terminal of the voltage generation circuit 17A. In the read operation, the internal voltage VI3 output from the boosting circuit 173 is supplied as a read voltage VCGRV to a word line (or a selected word line) WLsel of the reading target via the driver 17B and the row decoder 18. The internal voltage VI4 output from the boosting circuit 174 is supplied as a read pass voltage VREAD to a word line (or a non-selected word line) WLusel of the non-reading target via the driver 17B and the row decoder 18.

The boosting circuit 175 generates and outputs an internal voltage VI5 used during an erase operation via an output terminal of the voltage generation circuit 17A. In the erase operation, the internal voltage VI5 output from the boosting circuit 175 is supplied as an erase voltage VERA to a source line SL of a block (or a selected block) of the erase target via the driver 17B.

### 1.1.3 Threshold Voltage Distribution of Memory Cell Transistor

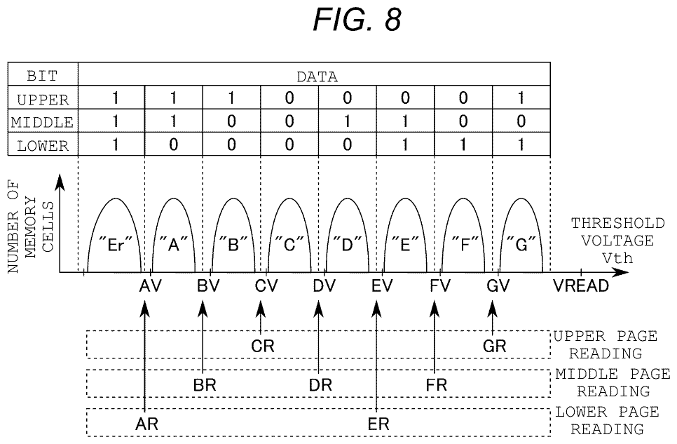

Next, a relation between data and a threshold voltage distribution taken by the memory cell transistors MT will be described. FIG. 8 is a diagram illustrating a relation between data and a threshold voltage distribution taken by the memory cell transistors MT.

Here, an example in which a triple-level cell (TLC) scheme capable of storing 3-bit data in one memory cell transistor MT is applied as a storage scheme for the memory cell transistor MT will be described. The embodiment can also be applied when another storage scheme such as a single-level cell (SLC) scheme capable of storing 1-bit data in one memory cell transistor MT, a multi-level cell (MLC) scheme capable of storing 2-bit data in one memory cell transistor MT, or a quad-level cell (QLC) scheme capable of storing 4-bit data in one memory cell transistor MT is used.

The 3-bit data that can be stored by the memory cell transistor MT is defined by a lower bit, a middle bit, and an upper bit. When the memory cell transistor MT stores 3 bits, the memory cell transistor MT can take any state among eight states in accordance with a plurality of threshold voltages. The eight states are referred to as states “Er”, “A”, “B”, “C”, “D”, “E”, “F”, and “G” in order from a low state. The plurality of memory cell transistors MT belonging to each of the states “Er”, “A”, “B”, “C”, “D”, “E”, “F”, and “G” form a distribution of threshold voltages illustrated in FIG. 8.

For example, data “111”, data “110”, data “100”, data “000”, data “010”, data “011”, data “001”, and data “101” are allocated to the states “Er”, “A”, “B”, “C”, “D”, “E”, “F”, and “G”, respectively. When the lower, middle, and upper bits are respectively “X”, “Y”, and “Z”, a line of the bits is “Z, Y, X”. The allocation of the data and the threshold voltage distribution can be set freely and selectively.

In order to read data stored in the memory cell transistor MT of the reading target, a state to which a threshold voltage of the memory cell transistor MT belongs is determined. In order to determine the state, read voltages AR, BR, CR, DR, ER, FR, and GR are used. Hereinafter, voltages that include the read voltages AR, BR, CR, DR, ER, FR, and GR and are applied to the memory cell transistor MT of the reading target to determine levels are referred to as read voltage VCGRV in some cases.

The state “Er” corresponds to, for example, a state in which data is erased (erased state). A threshold voltage of the memory cell transistor MT belonging to the state “Er” is lower than the voltage AR and has, for example, a negative value.

The states “A” to “G” correspond to states in which charges are injected to the charge storage layers and data is written in the memory cell transistors MT, and the threshold voltages of the memory cell transistors MT belonging to the states “A” to “G” have, for example, positive values. The threshold voltage of the memory cell transistor MT belonging to the state “A” is higher than the read voltage AR and is equal to or lower than the read voltage BR. A threshold voltage of the memory cell transistor MT belonging to the state “B” is higher than the read voltage BR and is equal to or lower than the read voltage CR. A threshold voltage of the memory cell transistor MT belonging to the state “C” is higher than the read voltage CR and is equal to or lower than the read voltage DR. A threshold voltage of the memory cell transistor MT belonging to the state “D” is higher than the read voltage DR and is equal to or lower than the read voltage ER. A threshold voltage of the memory cell transistor MT belonging to the state “E” is higher than the read voltage ER and is equal to or lower than the read voltage FR. A threshold voltage of the memory cell transistor MT belonging to the state “F” is higher than the read voltage FR and is equal to or lower than the read voltage GR. A threshold voltage of the memory cell transistor MT belonging to the state “G” is higher than the read voltage GR and is lower than the voltage VREAD.

The voltage VREAD is a voltage applied to the word line WL connected to the memory cell transistor MT of a cell unit CU of a non-reading target and is higher than a threshold voltage of the memory cell transistor MT in a certain state. Therefore, the memory cell transistor MT in which the voltage VREAD is applied to the control gate enters an ON state irrespective of data to be stored.

A verification voltage used for each write operation is set between the threshold voltage distributions adjacent to each other. Specifically, verification voltages AV, BV, CV, DV, EV, FV, and GV are set to correspond to the states “A”, “B”, “C”, “D”, “E”, “F”, and “G”, respectively. For example, the verification voltages AV, BV, CV, DV, EV, FV, and GV are set to be slightly higher than the read voltages AR, BR, CR, DR, ER, FR, and GR, respectively.

As described above, each memory cell transistor MT is set to any of the eight states and 3-bit data can be stored. Writing and reading are executed in units of pages in one cell unit CU. When the memory cell transistor MT stores 3-bit data, lower, middle, and upper bits are respectively allocated to three pages in one cell unit CU. Pages in which data is written in a single write operation or pages in which data is read in a single read operation with respect to the lower, middle, and upper bits, that is, a set including lower bits, a set including middle bits, and a set including upper bits held in the cell unit CU, are referred to as lower, middle, and upper pages, respectively.

When the allocation of the data is applied, the lower pages are confirmed by a read operation using the read voltages AR and ER. The middle pages are confirmed by a read operation using the read voltages BR, DR, and FR. The upper pages are confirmed by a read operation using the read voltages CR and GR.

### 1.2 Operation of Memory System

An operation of the semiconductor memory device 10 and an operation of the memory system 1 according to the first embodiment will be described.

First, an overview of the operation of the semiconductor memory device 10 according to the first embodiment will be described.

Here, it is assumed that the semiconductor memory device 10 ascertains that writing, reading, or erasing are consecutively executed. For example, the semiconductor memory device 10 may ascertain that operations are consecutively executed with a command transmitted from the memory controller 20 or may ascertain that operations are consecutively executed by another method. Hereinafter, two operations consecutively executed in the semiconductor memory device 10 are referred to as first and second operations.

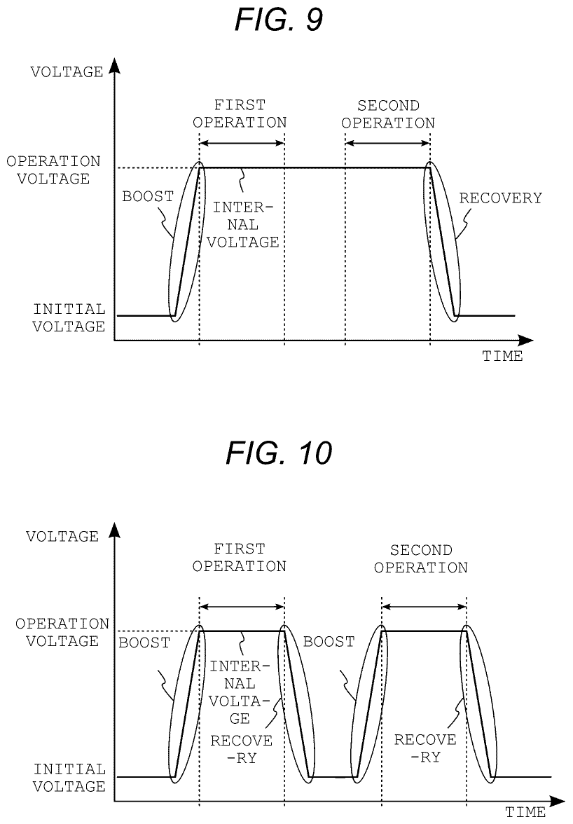

FIG. 9 is a diagram illustrating an internal voltage in a consecutive operation according to the first embodiment. In FIG. 9, the horizontal axis represents a time and the vertical axis represents a voltage.

Before the first operation starts, the voltage generation circuit 17A boosts an initial voltage (for example, the power voltage VDD) to generate an internal voltage. The internal voltage is boosted to an operation voltage. The semiconductor memory device 10 executes the first operation using the internal voltage. When the first operation ends, the semiconductor memory device 10 holds a voltage level (or a voltage value) of the internal voltage without dropping the internal voltage generated by the voltage generation circuit 17A, that is, executing a recovery. Subsequently, after the first operation ends, the semiconductor memory device 10 executes the second operation using the internal voltage generated by the voltage generation circuit 17A.

Hereinafter, a consecutive operation according to a comparative example will be described to compare the first embodiment to the comparative example.

FIG. 10 is a diagram illustrating an internal voltage in a consecutive operation according to the comparative example. In the comparative example, a semiconductor memory device executes the first operation using the internal voltage. When the first operation ends, the semiconductor memory device executes a recovery to the internal voltage generated by a voltage generation circuit and drops the internal voltage to the initial voltage. Thereafter, the semiconductor memory device again executes a boosting process in which the voltage generation circuit boosts the initial voltage to the internal voltage to generate the internal voltage. Subsequently, the semiconductor memory device 10 executes the second operation using the internal voltage generated through the recovery and the boosting process after the first operation ends.

As described above, in the present embodiment, the recovery and the boosting process executed in the comparative example can be omitted. Accordingly, it is possible to shorten a time between the first and second operations. That is, it is possible to shorten a time from end of the first operation to start of the second operation. When a period from the first operation to the second operation is short, it is possible to reduce power consumption occurring in a case where the first and second operations are consecutively executed.

Thereafter, an operation mode in which the semiconductor memory device 10 is set so that a voltage level of the internal voltage is held without dropping the internal voltage output from the voltage generation circuit 17A and used in the first operation after the first operation is executed using the internal voltage is referred to as a voltage suspension mode.

Next, an operation of the memory system 1 according to the first embodiment will be described. An operation in a case where an operation of each of a write operation, a read operation, and an erase operation is consecutively executed will be described below.

### 1.3 Case in which Write Operation is Consecutively Executed

An operation in a case where a write operation is consecutively executed will be described.

For example, a case in which the memory cell transistor MT can store 3-bit data and lower, middle, and upper pages are written in the memory cell transistors connected to one cell unit CU, that is, one word line, will be described as an example.

### 1.3.1 First Example

In a first example, a command to give an instruction for the voltage suspension mode is transmitted from the memory controller 20 to the semiconductor memory device 10 before a command related to a write operation is transmitted from the memory controller 20 to the semiconductor memory device 10. Accordingly, the semiconductor memory device 10 is set to the voltage suspension mode.

If the semiconductor memory device 10 is set to the voltage suspension mode, the voltage generation circuit 17A of the semiconductor memory device 10 generates and outputs the internal voltages generated in one write operation as they are, even when the one write operation ends until end of consecutive write operations instructed with the command. Thereafter, when the consecutive write operations end, the voltage suspension mode of the semiconductor memory device 10 is terminated and the voltage generation circuit 17A drops the internal voltages to the initial voltage.

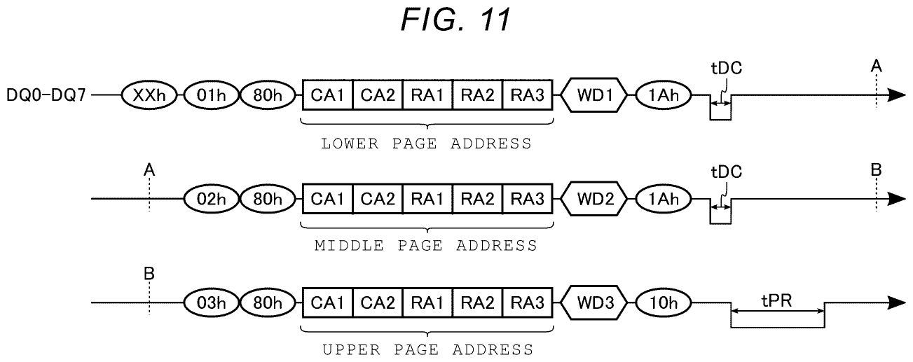

FIG. 11 is a diagram illustrating a first example of a command sequence in a write operation according to the first embodiment.

Before a command related to the write operation is transmitted from the memory controller 20 to the semiconductor memory device 10, a prefix command “XXh” determined in advance is transmitted. The prefix command “XXh” is a command to give an instruction for the voltage suspension mode and is a command to instruct the voltage generation circuit 17A to generate (or output) the internal voltages generated (or output) during the write operation as they are despite of end of one write operation until end of the consecutive write operations by a subsequently transmitted command. In the prefix command “XXh”, X indicates a hexadecimal numeral value determined in advance and h indicates that XX is hexadecimal. In other commands, the same applies to X and h.

As illustrated in FIG. 11, the memory controller 20 first transmits the prefix command “XXh” to the semiconductor memory device 10 using signals DQ0 to DQ7. The prefix command “XXh” is a command to give an instruction for the voltage suspension mode to the semiconductor memory device 10.

When the prefix command “XXh” is received, the sequencer 16 of the semiconductor memory device 10 holds the internal voltages output from the voltage generation circuit 17A, as they are, based on the prefix command “XXh” from end of the first write operation to start of the subsequent second write operation. That is, the internal voltages output from the voltage generation circuit 17A are maintained, as they are, from the end of the first write operation to the start of the second write operation.

Subsequently, the memory controller 20 transmits a command “01h” and a command “80h” to the semiconductor memory device 10 in order using the signals DQ0 to DQ7. The command “01h” is a page selection command and is a command for notifying that a command, an address, and data transmitted after the command “01h” are related to the lower page. The command “80h” is a command for notifying of an input of data and the write operation.

Subsequently, the memory controller 20 transmits addresses “CA1, CA2, RA1, RA2, and RA3” and data “WD1” to the semiconductor memory device 10 using the signals DQ0 to DQ7. The data “WD1” is lower page data serving as writing target data. The addresses “CA1, CA2, RA1, RA2, and RA3” are addresses for designating storage locations at which the data “WD1” is written. The addresses “CA1 and CA2” are column addresses for designating storage locations on a column side. The addresses “RA1, RA2, and RA3” are row addresses for designating a storage locations on a row side. That is, the addresses “CA1, CA2, RA1, RA2, and RA3” are used to designate memory cell transistors connected to a word line of the writing target in which the lower page data is written. Here, the addresses are indicated with five cycles, but any number of cycles may be used.

Subsequently, the memory controller 20 transmits the command “1Ah” to the semiconductor memory device 10 using the signals DQ0 to DQ7. The command “1Ah” is a command for instructing a first latch circuit in the sense amplifier 19C to store the data “WD1”. When the command “1Ah” is received, the sequencer 16 of the semiconductor memory device 10 causes the first latch circuit in the sense amplifier 19C to temporarily store the data “WD1” in time tDC.

Subsequently, the memory controller 20 transmits a command “02h” and the command “80h” to the semiconductor memory device 10 using the signals DQ0 to DQ7. The command “02h” is a page selection command and is a command for notifying that a command, an address, and data transmitted after the command “02h” are related to the middle page. The command “80h” is a command for notifying of an input of data and the write operation.

Subsequently, the memory controller 20 transmits the addresses “CA1, CA2, RA1, RA2, and RA3” and data “WD2” to the semiconductor memory device 10 using the signals DQ0 to DQ7. The data “WD2” is middle page data serving as writing target data. The addresses “CA1, CA2, RA1, RA2, and RA3” are addresses for designating storage locations at which the data “WD2” is written. The addresses “CA1 and CA2” are column addresses for designating storage locations on the column side. The addresses “RA1, RA2, and RA3” are row addresses for designating a storage location on the row side. That is, the addresses “CA1, CA2, RA1, RA2, and RA3” are used to designate memory cell transistors connected to a word line of the writing target in which the middle page data is written. Here, the addresses are indicated with five cycles, but any number of cycles may be used.

Subsequently, the memory controller 20 transmits the command “1Ah” to the semiconductor memory device 10 using the signals DQ0 to DQ7. The command “1Ah” is a command for instructing a second latch circuit in the sense amplifier 19C to store the data “WD2”. When the command “1Ah” is received, the sequencer 16 causes the second latch circuit in the sense amplifier 19C to temporarily store the data “WD2” in time tDC.

Subsequently, the memory controller 20 transmits a command “03h” and the command “80h” to the semiconductor memory device 10 in order using the signals DQ0 to DQ7. The command “03h” is a page selection command and is a command for notifying that a command, an address, and data transmitted after the command “03h” are related to the upper page. The command “80h” is a command for notifying of an input of data and the write operation.

Subsequently, the memory controller 20 transmits the addresses “CA1, CA2, RA1, RA2, and RA3” and data “WD3” to the semiconductor memory device 10 using the signals DQ0 to DQ7. The data “WD3” is upper page data serving as writing target data. The addresses “CA1, CA2, RA1, RA2, and RA3” are addresses for designating storage locations at which the data “WD3” is written. The addresses “CA1 and CA2” are column addresses for designating storage locations on the column side. The addresses “RA1, RA2, and RA3” are row addresses for designating a storage locations on the row side. That is, the addresses “CA1, CA2, RA1, RA2, and RA3” are used to designate memory cell transistors connected to a word line of the writing target in which the upper page data is written. Here, the addresses are indicated with five cycles, but any number of cycles may be used.

Subsequently, the memory controller 20 transmits the command “10h” to the semiconductor memory device 10 using the signals DQ0 to DQ7. The command “10h” is a command to give an instruction to execute the write operation, that is, to give an instruction for starting a program operation to be described below. When the command “10h” is received, the sequencer 16 writes the data “WD1, WD2, and WD3” at time tPR, that is, the lower page data, the middle page data, and the upper page data, in the memory cell transistors designated with the addresses.

### 1.3.2 Second Example

In a second example, the semiconductor memory device 10 is set to the voltage suspension mode using a “Set Feature” command before a command related to the write operation is transmitted from the memory controller 20 to the semiconductor memory device 10. When the semiconductor memory device 10 is set to the voltage suspension mode with the “Set Feature” command, the voltage generation circuit 17A of the semiconductor memory device 10 generates and outputs the internal voltages generated in the write operation, as they are, despite end of the write operation. Thereafter, after the consecutive write operations end, the “Set Feature” command is used again to terminate the voltage suspension mode of the semiconductor memory device 10.

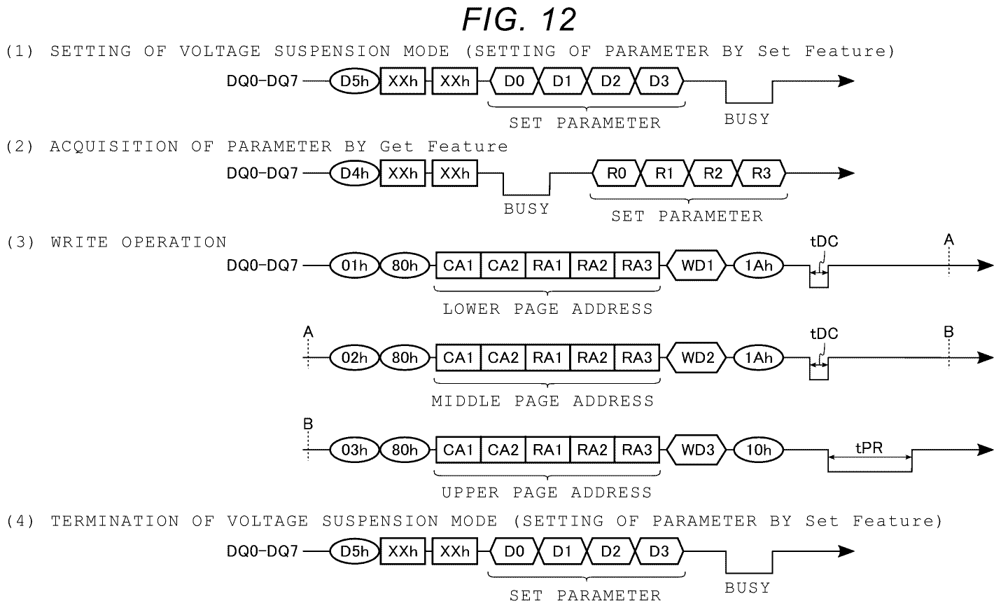

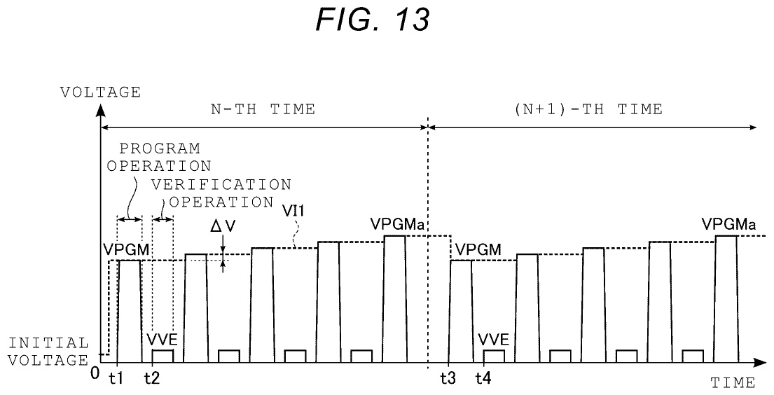

FIG. 12 is a diagram illustrating the second example of a command sequence in the write operation according to the first embodiment.

Commands, addresses, and data shown in (1), (2), (3), and (4) in FIG. 12 are transmitted from the memory controller 20 to the semiconductor memory device 10.

First, (1) setting of a parameter with a “Set Feature” command is executed to set the semiconductor memory device 10 to the voltage suspension mode. Subsequently, (2) the acquisition of the parameter with the “Get Feature” command is executed. The acquisition of the parameter with the “Get Feature” command is executed to check whether the setting of the parameter is correctly executed, and is not executed in some cases. Subsequently, (3) the write operation is executed. Thereafter, (4) setting of a parameter with the “Set Feature” command is executed to terminate the voltage suspension mode set in the semiconductor memory device 10.

Hereinafter, (1) to (4) will be described in detail.

### (1) Setting of Voltage Suspension Mode

First, the memory controller 20 transmits a command “D5h”, a logical unit number (LUN) address “XXh”, and a feature address XXh” to the semiconductor memory device 10 using the signals DQ0 to DQ7. The command “D5h” is a command for notifying that an address and data transmitted after the command “D5h” are related to the setting of the parameter with the “Set Feature” command. The LUN address “XXh” is an address for designating a unit of a setting target with the “Set Feature” command. The feature address “XXh” is an address at which the parameter set with the “Set Feature” command is stored.

Subsequently, the memory controller 20 transmits the pieces of data “D0, D1, D2, and D3” to the semiconductor memory device 10 using the signals DQ0 to DQ7. The pieces of data “D0, D1, D2, and D3” are parameters set with the “Set Feature” command. With the parameter set, the semiconductor memory device 10 is set to the voltage suspension mode. When the semiconductor memory device 10 is set to the voltage suspension mode, the voltage generation circuit 17A of the semiconductor memory device 10 generates (or outputs) the internal voltages generated (or output) during the write operation as they are despite end of the write operation.

(2) Acquisition of Parameter with Get Feature

The memory controller 20 transmits the command “D4h”, the LUN address “XXh”, and the feature address “XXh” to the semiconductor memory device 10 using the signals DQ0 to DQ7. The command “D4h” is a command for notifying that the address transmitted after the command “D4h” is related to the acquisition of the parameter with the “Get Feature” command. The LUN address “XXh” is an address for designating a unit of an acquisition target with the “Get Feature” command. The feature address “XXh” is an address at which a parameter acquired with the “Get Feature” command is stored. Accordingly, in the semiconductor memory device 10, the parameter set with the “Set Feature” command is read. Subsequently, the pieces of read data R0, R1, R2, and R3 are transmitted from the semiconductor memory device 10 to the memory controller 20. Accordingly, the memory controller 20 can ascertain whether the parameter set with the “Set Feature” command is correctly set, that is, the semiconductor memory device 10 is set to the voltage suspension mode.

### (3) Write Operation

The write operation is similar to the operation excluding the prefix command “XXh” in the first example.

First, the memory controller 20 transmits the command “01h” and the command “80h” to the semiconductor memory device 10 using the signals DQ0 to DQ7. Subsequently, the memory controller 20 transmits the addresses “CA1, CA2, RA1, RA2, and RA3” and the data “WD1” to the semiconductor memory device 10 using the signals DQ0 to DQ7. Further, the memory controller 20 transmits the command “1Ah” to the semiconductor memory device 10 using the signals DQ0 to DQ7.

Subsequently, the memory controller 20 transmits the command “02h” and the command “80h” to the semiconductor memory device 10 using the signals DQ0 to DQ7. Subsequently, the memory controller 20 transmits the addresses “CA1, CA2, RA1, RA2, and RA3” and the data “WD2” to the semiconductor memory device 10 in order using the signals DQ0 to DQ7. Further, the memory controller 20 transmits the command “1Ah” to the semiconductor memory device 10 using the signals DQ0 to DQ7.

Subsequently, the memory controller 20 transmits the command “03h” and the command “80h” to the semiconductor memory device 10 in order using the signals DQ0 to DQ7. Subsequently, the memory controller 20 transmits the addresses “CA1, CA2, RA1, RA2, and RA3” and the data “WD3” to the semiconductor memory device 10 using the signals DQ0 to DQ7. Further, the memory controller 20 transmits the command “10h” to the semiconductor memory device 10 using the signals DQ0 to DQ7. When the command “10h” is received, the sequencer 16 writes the pieces of data “WD1, WD2, and WD3” at time tPR, that is, the lower page data, the middle page data, and the upper page data, in the memory cell transistors designated with the addresses.

### (4) Termination of Setting of Voltage Suspension Mode

The memory controller 20 transmits the command “D5h”, the LUN address “XXh”, and the feature address “XXh” to the semiconductor memory device 10 using the signals DQ0 to DQ7. The command “D5h” indicates that the data and the address transmitted after the command “D5h” are related to the setting of the parameter with the “Set Feature” command. The LUN address “XXh” and the feature address “XXh” are similar to the above-described addresses.

Subsequently, the memory controller 20 transmits the pieces of data “D0, D1, D2, and D3” to the semiconductor memory device 10 using the signals DQ0 to DQ7. The pieces of data “D0, D1, D2, and D3” are parameters set with the “Set Feature” command. With the parameter set, the voltage suspension mode set in the semiconductor memory device 10 is terminated. When the setting of the voltage suspension mode is terminated and the write operation ends, the voltage generation circuit 17A of the semiconductor memory device 10 drops the internal voltages generated during the write operation to the initial voltage.

As described above, the setting and the termination of the voltage suspension mode in the write operation are executed using the “Set Feature” command.

### 1.3.3 Write Operation in First and Second Examples

A write operation executed in the above-described first and second examples on the memory cell transistors will be described.

As described above, in the write operation, the internal voltage VI1 output from the boosting circuit 171 of the voltage generation circuit 17A is supplied as the write voltage VPGM to a selected word line WLsel of the writing target via the driver 17B and the row decoder 18. Here, the internal voltage VI1 output from the boosting circuit 171 and the write voltage VPGM supplied to the selected word line WLsel of the writing target will be described as examples.

FIG. 13 is a diagram illustrating the internal voltage VI1 and the write voltage VPGM in the write operation according to the first embodiment. In FIG. 13, the write voltage VPGM is indicated by a solid line and the internal voltage VI1 is indicated by a dotted line.

The write operation includes a program operation and a program verification operation. The program operation is an operation of injecting charges into, for example, an insulating layer (that is, the charge storage layer) 52 of the memory cell transistor and raising a threshold voltage of the memory cell transistor by applying the write voltage VPGM to the gate electrode of the memory cell transistor. The program verification operation is a read operation of verifying whether the threshold voltage of the memory cell transistor generated by applying the write voltage VPGM reaches a target voltage.

The write operation is executed on a plurality of cell units a plurality of times using the plurality of write voltages VPGM. N-th and (N+1)-th write operations illustrated in FIG. 13 are write operations on the memory cell transistors connected to two word lines among the write operations executed on the memory cell transistors connected to the plurality of word lines. In the N-th write operation, the internal voltage VI1 output from the boosting circuit 171 is supplied as the write voltage VPGM to a first selected word line WLsel. In the (N+1)-th write operation, the internal voltage VI1 is set to the write voltage VPGM and is supplied to a second selected word line WLsel.

The N-th write operation is executed as follows.

As illustrated in FIG. 13, at time t1, the program operation is executed on the memory cell transistor using the write voltage VPGM. In the program operation, the internal voltage VI1 is output from the boosting circuit 171 of the voltage generation circuit 17A, and the internal voltage VI1 is supplied as the write voltage VPGM to the selected word line WLsel of the writing target.

Subsequently, at time t2, the program verification operation is executed on the memory cell transistor using a verification voltage VVE. In the program verification operation, the verification voltage VVE is supplied to the selected word line WLsel.

In the program verification operation, when the threshold voltage of the memory cell transistor does not reach a predetermined threshold voltage, that is, verification by the program verification operation fails, the write voltage VPGM increases by a given voltage ΔV, the program operation is executed again, and the program verification operation is executed. The program operation and the program verification operation are repeatedly executed until the verification by the program verification operation passes.

In the program verification operation, when the threshold voltage of the memory cell transistor reaches the predetermined threshold voltage, that is, the verification by the program verification operation passes, the N-th write operation ends.

The internal voltage VI1 output from the boosting circuit 171 is set to the write voltage VPGM in the first program operation in the N-th write operation. Thereafter, whenever the program operation is repeated, the internal voltage is boosted by the given voltage AV to be set to a write voltage “VPGM+R·ΔV. R indicates the number of times the program operation is repeatedly executed.

When the N-th write operation ends, the internal voltage VI1 (that is, the write voltage VPGM) generated by the boosting circuit 171 at the time of ending of the N-th write operation is generated and output, as it is, to the boosting circuit 171 until the (N+1)-th write operation starts.

In the write operation, a plurality states are set in the memory cell transistors. In the program verification operation, a plurality of verification voltages are used in accordance with the plurality of written states. For example, when the above-described seven states “A” to “G” are set, verification voltages AV to GV are used in accordance with the states “A” to “G”. Here, the plurality of verification voltages are collectively indicated or any of the plurality of verification voltages is indicated by the verification voltage VVE.

Subsequently, the (N+1)-th write operation is executed as follows.

At time t3, the program operation is executed on the memory cell transistor using the write voltage VPGM. In the program operation, the internal voltage VI1 (that is, a write voltage VPGMa) generated by the boosting circuit 171 when the N-th write operation ends is set to the write voltage VPGM and is supplied to the selected word line WLsel.

Subsequently, at time t4, the program verification operation is executed on the memory cell transistor using the verification voltage VVE. In the program verification operation, the verification voltage VVE is supplied to the selected word line WLsel.

When the verification by the program verification operation fails, the write voltage VPGM increases by the given voltage ΔV, the program operation is executed again, and the program verification operation is executed. The program operation and the program verification operation are repeatedly executed until the verification by the program verification operation passes. When the verification by the program verification operation passes, the (N+1)-th write operation ends.

The internal voltage VI1 output from the boosting circuit 171 is set to the write voltage VPGM in the first program operation in the (N+1)-th write operation. Thereafter, whenever the program operation is repeated, the internal voltage is boosted by the given voltage AV to be set to the write voltage “VPGM+R·ΔV. R indicates the number of times the program operation is repeatedly executed.

When the (N+1)-th write operation ends, the internal voltage VI1 remains to be held to the write voltage VPGMa used in the final program operation in the (N+1)-th write operation.

Hereinafter, a write operation according to a comparative example will be described to compare the first embodiment to the comparative example.

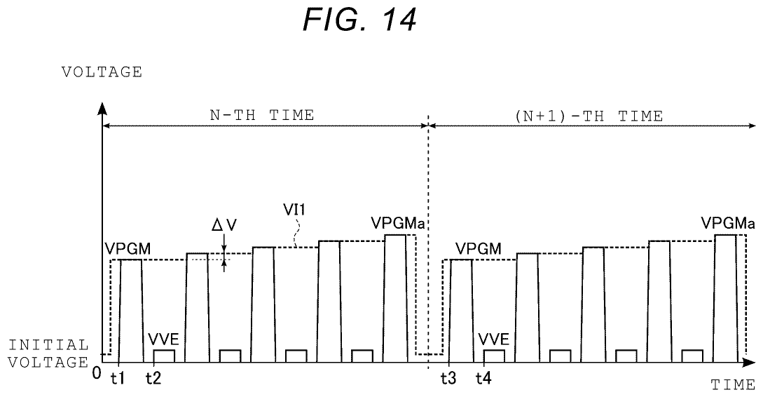

FIG. 14 is a diagram illustrating the internal voltage VI1 and the write voltage VPGM in the write operation according to the comparative example. In the comparative example, after the N-th write operation ends, the internal voltage VI1 (that is, the write voltage VPGMa) generated by the boosting circuit 171 is dropped to the initial voltage (for example, the power voltage VDD). Thereafter, in the first program operation of the (N+1)-th write operation, the internal voltage VI1 of the boosting circuit 171 is boosted to the write voltage VPGM and is used in the program operation. Therefore, in the comparative example, the internal voltage VI1 is dropped from the write voltage VPGMa to the initial voltage. Thereafter, a certain amount of time is required to boost the internal voltage from the initial voltage to the write voltage VPGM.

In the write operation according to the first embodiment, however, the internal voltage VI1 (that is, the voltage VPGMa) generated by the boosting circuit 171 at the time of ending of the N-th write operation is used in the first program operation in the (N+1)-th write operation. That is, the internal voltage VI1 (that is, the voltage VPGMa) of the boosting circuit 171 is set to the voltage VPGM and is supplied to the selected word line WLsel.

Since a voltage difference between the write voltage VPGMa and the write voltage VPGM is small, a period of time needed for setting the internal voltage VI1 from the voltage VPGMa to the voltage VPGM is shorter than a time for boosting the internal voltage VI1 from the initial voltage to the write voltage VPGM. Therefore, it is possible to shorten a time between the N-th write operation and the (N+1)-th write operation. That is, it is possible to shorten a time from end of the N-th write operation to start of the (N+1)-th write operation.

The write voltage VPGM and the internal voltage VI1 of the boosting circuit 171 are described above, but an embodiment is not limited thereto. The same applies to other voltages and internal voltages of the boosting circuits corresponding to the other voltages used in the write operation. When the internal voltages at the time of ending of the N-th write operation are held and the internal voltages are used in the (N+1)-th write operation, it is possible to shorten a time from end of the N-th write operation to start of the (N+1)-th write operation.

### 1.4 Case in Which Read Operation Is Consecutively Executed

An operation in a case where the read operation is consecutively executed will be described.

For example, when the memory cell transistor MT stores 3-bit data, a plurality of read operations are executed on one cell unit CU, that is, the memory cell transistors connected to one word line, and data of the lower page, the middle page, and the upper page is read.

### 1.4.1 First Example

In a first example, before a command related to a read operation is transmitted from the memory controller 20 to the semiconductor memory device 10, a command to give an instruction for the voltage suspension mode is transmitted from the memory controller 20 to the semiconductor memory device 10. Accordingly, the semiconductor memory device 10 is set to the voltage suspension mode.

When the semiconductor memory device 10 is set to the voltage suspension mode, the voltage generation circuit 17A of the semiconductor memory device 10 generates and outputs the internal voltages generated during the read operation, as they are, despite end of one read operation until consecutive read operations instructed with the command end. Thereafter, after the consecutive read operations end, the voltage suspension mode of the semiconductor memory device 10 is terminated and the voltage generation circuit 17A drops the internal voltages to the initial voltage.

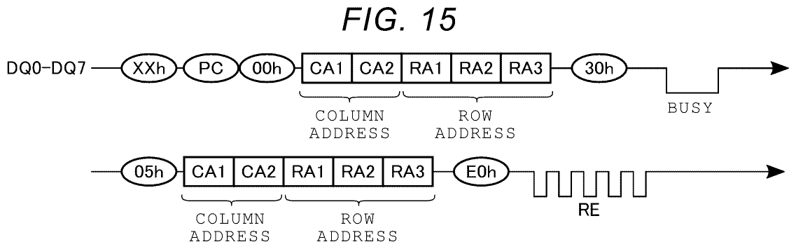

FIG. 15 is a diagram illustrating the first example of a command sequence in a read operation according to the first embodiment.

Before a command related to the read operation is transmitted from the memory controller 20 to the semiconductor memory device 10, the prefix command “XXh” determined in advance is transmitted. The prefix command “XXh” is a command to give an instruction for the voltage suspension mode and is a command to instruct the voltage generation circuit 17A to generate (or output) the internal voltages generated (or output) during the read operation despite end of one read operation as they are until end of the consecutive read operations by a subsequently transmitted command. In the prefix command “XXh”, X indicates a hexadecimal numeral value determined in advance and h indicates that XX is hexadecimal. In other commands, the same applies to X and h.

As illustrated in FIG. 15, the memory controller 20 first transmits the prefix command “XXh” to the semiconductor memory device 10 using signals DQ0 to DQ7. The prefix command “XXh” is a command to give an instruction for the voltage suspension mode to the semiconductor memory device 10.

When the prefix command “XXh” is received, the sequencer 16 of the semiconductor memory device 10 holds the internal voltages output from the voltage generation circuit 17A, as they are, based on the prefix command “XXh” from end of the first read operation to start of the subsequent second read operation. That is, the internal voltages output from the voltage generation circuit 17A are held, as they are, for a predetermined time from the end of the first read operation to the start of the second read operation.

Subsequently, the memory controller 20 transmits a command “PC” and a command “00h” to the semiconductor memory device 10 using the signals DQ0 to DQ7. The command “PC” is the command “01h”, “02h”, or “03h”. The command “01h” is a command for notifying that a command, an address, and data transmitted after the command “01h” are related to the lower page. The command “02h” is a command for notifying that a command, an address, and data transmitted after the command “02h” are related to the middle page. The command “03h” is a command for notifying that a command, an address, and data transmitted after the command “03h” are related to the upper page. The command “00h” is a command for notifying of an input of addresses and a read operation.

Subsequently, the memory controller 20 transmits addresses “CA1, CA2, RA1, RA2, and RA3” to the semiconductor memory device 10 using the signals DQ0 to DQ7. The addresses “CA1, CA2, RA1, RA2, and RA3” are addresses for designating storage locations of a reading target in the memory cell array 11. The addresses “CA1 and CA2” are column addresses for designating storage locations on a column side. The addresses “RA1, RA2, and RA3” are row addresses for designating a storage locations on a row side. That is, the addresses “CA1, CA2, RA1, RA2, and RA3” are used to designate memory cell transistors that are reading targets of the page data indicated by the command “PC”. Here, the addresses are indicated with five cycles, but any number of cycles may be used.

Subsequently, the memory controller 20 transmits the command “30h” to the semiconductor memory device 10 using the signals DQ0 to DQ7. The command “30h” is a command for giving an instruction to start the read operation on the memory cell transistor of the reading target. When the command “30h” is received, the sequencer 16 reads data stored in the memory cell transistor designated with the address.

Subsequently, the memory controller 20 transmits a command “05h” to the semiconductor memory device 10 using the signals DQ0 to DQ7. The command “05h” is a command for notifying of an input of the addresses and an output of data.

Subsequently, the memory controller 20 transmits the addresses “CA1, CA2, RA1, RA2, and RA3” to the semiconductor memory device 10 in order using the signals DQ0 to DQ7. The addresses “CA1, CA2, RA1, RA2, and RA3” are addresses of read data that are output targets.

Subsequently, the memory controller 20 transmits the command “E0h” to the semiconductor memory device 10 using the signals DQ0 to DQ7. The command “E0h” is a command for giving an instruction to output the read data designated with the addresses to the memory controller 20. When the command “E0h” is received, the sequencer 16 outputs the read data designated with the addresses to the memory controller 20.

### 1.4.2 Second Example

In a second example, the semiconductor memory device 10 is set to the voltage suspension mode using a “Set Feature” command before a command related to the read operation is transmitted from the memory controller 20 to the semiconductor memory device 10. When the semiconductor memory device 10 is set to the voltage suspension mode with the “Set Feature” command, the voltage generation circuit 17A of the semiconductor memory device 10 generates and outputs the internal voltages generated in the read operation, as they are, despite end of the read operation. Thereafter, after the consecutive read operations end, the “Set Feature” command is used again to terminate the voltage suspension mode of the semiconductor memory device 10.

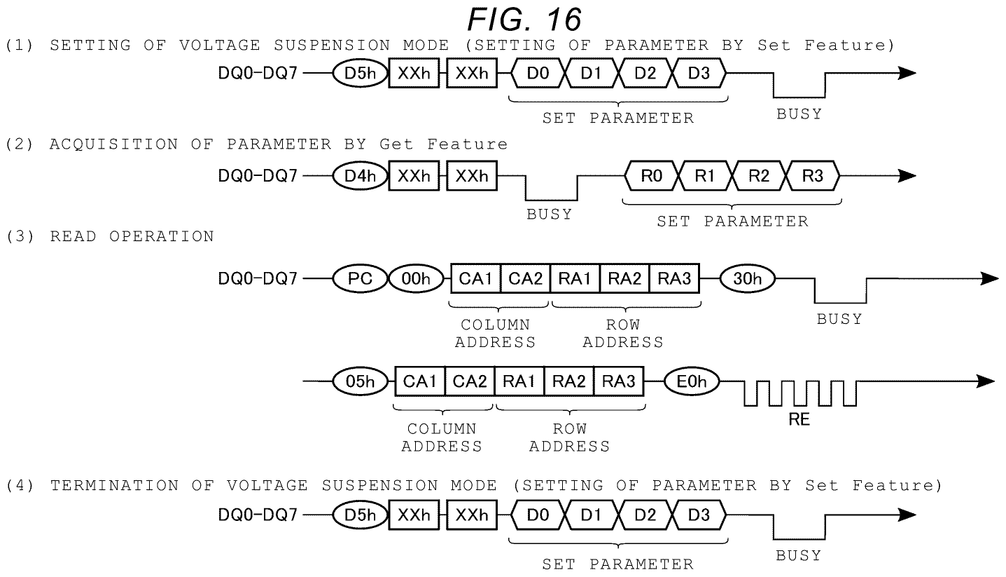

FIG. 16 is a diagram illustrating the second example of a command sequence in the read operation according to the first embodiment.

Commands, addresses, and data shown in (1), (2), (3), and (4) in FIG. 16 are transmitted from the memory controller 20 to the semiconductor memory device 10.

First, (1) setting of a parameter with a “Set Feature” command is executed to set the semiconductor memory device 10 to the voltage suspension mode. Subsequently, (2) the acquisition of the parameter with the “Get Feature” command is executed. The acquisition of the parameter with the “Get Feature” command is executed to check whether the setting of the parameter is correctly executed, and is not executed in some cases. Subsequently, (3) the read operation is executed. Thereafter, (4) setting of a parameter with the “Set Feature” command is executed to terminate the voltage suspension mode set in the semiconductor memory device 10.

Hereinafter, (1) to (4) will be described in detail.

### (1) Setting of Voltage Suspension Mode

First, the memory controller 20 transmits a command “D5h”, a LUN address “XXh”, and a feature address XXh” to the semiconductor memory device 10 using the signals DQ0 to DQ7. The command “D5h” is a command for notifying that an address and data transmitted after the command “D5h” are related to the setting of the parameter with the “Set Feature” command. The LUN address “XXh” is an address for designating a unit of a setting target with the “Set Feature” command. The feature address “XXh” is an address at which the parameter set with the “Set Feature” command is stored.

Subsequently, the memory controller 20 transmits the pieces of data “D0, D1, D2, and D3” to the semiconductor memory device 10 using the signals DQ0 to DQ7. The pieces of data “D0, D1, D2, and D3” are parameters set with the “Set Feature” command. With the parameter set, the semiconductor memory device 10 is set to the voltage suspension mode. When the semiconductor memory device 10 is set to the voltage suspension mode, the voltage generation circuit 17A of the semiconductor memory device 10 generates (or outputs) the internal voltages generated (or output) during the read operation as they are despite end of the read operation.

### (2) Acquisition of Parameter by Get Feature

The memory controller 20 transmits the command “D4h”, the LUN address “XXh”, and the feature address “XXh” to the semiconductor memory device 10 in order using the signals DQ0 to DQ7. The command “D4h” is a command for notifying that the address transmitted after the command “D4h” is related to the acquisition of the parameter with the “Get Feature” command. The LUN address “XXh” is an address for designating a unit of an acquisition target with the “Get Feature” command. The feature address “XXh” is an address at which a parameter acquired with the “Get Feature” command is stored. Accordingly, in the semiconductor memory device 10, the parameter set with the “Set Feature” command is read. Subsequently, the read pieces of data R0, R1, R2, and R3 are transmitted from the semiconductor memory device 10 to the memory controller 20. Accordingly, the memory controller 20 can ascertain whether the parameter set with the “Set Feature” command is correctly set, that is, the semiconductor memory device 10 is set to the voltage suspension mode.

### (3) Read Operation

The read operation is similar to the operation excluding the prefix command “XXh” in the first example.

First, the memory controller 20 transmits the command “PC” and the command “00h” to the semiconductor memory device 10 using the signals DQ0 to DQ7. Subsequently, the memory controller 20 transmits the addresses “CA1, CA2, RA1, RA2, and RA3” to the semiconductor memory device 10 in order using the signals DQ0 to DQ7. Further, the memory controller 20 transmits the command “30h” to the semiconductor memory device 10 using the signals DQ0 to DQ7.

Subsequently, the memory controller 20 transmits the command “05h” to the semiconductor memory device 10 using the signals DQ0 to DQ7. Subsequently, the memory controller 20 transmits the addresses “CA1, CA2, RA1, RA2, and RA3” to the semiconductor memory device 10 in order using the signals DQ0 to DQ7. Further, the memory controller 20 transmits the command “E0h” to the semiconductor memory device 10 using the signals DQ0 to DQ7. When the command “E0h” is received, the sequencer 16 outputs the read data designated with the addresses to the memory controller 20.

### (4) Termination of Setting of Voltage Suspension Mode

The memory controller 20 transmits the command “D5h”, the LUN address “XXh”, and the feature address “XXh” to the semiconductor memory device 10 using the signals DQ0 to DQ7. The command “D5h” indicates that the data and the address transmitted after the command “D5h” are related to the setting of the parameter with the “Set Feature” command. The LUN address “XXh” and the feature address “XXh” are similar to the above-described addresses.

Subsequently, the memory controller 20 transmits the pieces of data “D0, D1, D2, and D3” to the semiconductor memory device 10 using the signals DQ0 to DQ7. The pieces of data “D0, D1, D2, and D3” are parameters set with the “Set Feature” command. With the parameter set, the voltage suspension mode set in the semiconductor memory device 10 is terminated. When the setting of the voltage suspension mode is terminated and the read operation ends, the voltage generation circuit 17A of the semiconductor memory device 10 drops the internal voltages generated during the read operation to the initial voltage.

As described above, the setting and the termination of the voltage suspension mode in the read operation are executed using the “Set Feature” command.

### 1.4.3 Read Operation in First and Second Examples

A read operation executed in the above-described first and second examples on the memory cell transistors will be described.

As described above, in the read operation, the internal voltage VI4 output from the boosting circuit 174 of the voltage generation circuit 17A is supplied as a read pass voltage VREAD to a non-selected word line WLusel of the non-reading target via the driver 17B and the row decoder 18. Here, the internal voltage VI4 output from the boosting circuit 174 and the read pass voltage VREAD supplied to the non-selected word line WLusel will be described as examples.

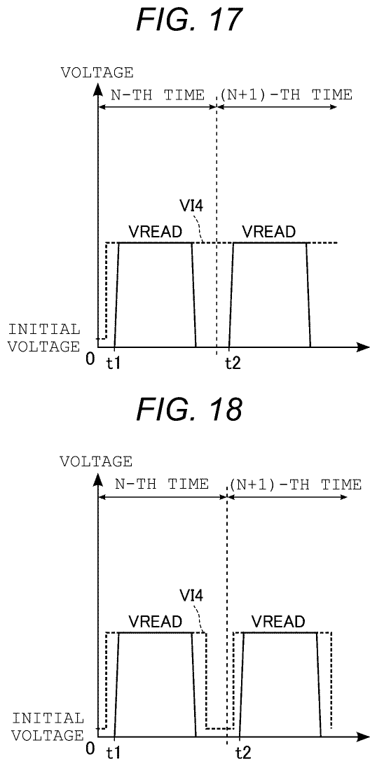

FIG. 17 is a diagram illustrating the internal voltage VI4 and the read pass voltage VREAD in the read operation according to the first embodiment. In FIG. 17, the read pass voltage VREAD is indicated by a solid line and the internal voltage VI4 is indicated by a dotted line.

The read operation is executed on a plurality of cell units a plurality of times using the plurality of read voltages VCGRV (not illustrated) and the read pass voltage VREAD. N-th and (N+1)-th read operations illustrated in FIG. 17 are read operations on the memory cell transistors connected to two word lines among the read operations executed on the memory cell transistors connected to the plurality of word lines. In the N-th read operation, the internal voltage VI4 output from the boosting circuit 174 is supplied as the read pass voltage VREAD to the non-selected word line WLusel other than the first selected word line WLsel. In the (N+1)-th read operation, the internal voltage VI4 is supplied as the read pass voltage VREAD to the non-selected word line WLusel other than the second selected word line WLsel. Here, the read operation on the plurality of cell units is illustrated, but the same applies to the read operation on one cell unit, that is, the memory cell transistors connected to one word line.

The N-th read operation is executed as follows.

As illustrated in FIG. 17, at time t1, the read operation is executed on the memory cell transistor using a read voltage VCGRV (not illustrated) and the read pass voltage VREAD. In the read operation, the internal voltage VI4 is output from the boosting circuit 174 of the voltage generation circuit 17A, and the internal voltage VI4 is supplied as the read pass voltage VREAD to the non-selected word line WLusel.

When the N-th read operation ends, the internal voltage VI4 (that is, the read pass voltage VREAD) generated by the boosting circuit 174 at the time of ending of the N-th read operation is generated and output, as it is, in the boosting circuit 174 until the (N+1)-th read operation starts.

Subsequently, the (N+1)-th read operation is executed as follows.

At time t2, the read operation is executed on the memory cell transistor using the read voltage VCGRV and the read pass voltage VREAD. In the read operation, the internal voltage VI4 (that is, a read pass voltage VREAD) generated by the boosting circuit 174 when the N-th read operation ends is supplied as the read pass voltage VREAD to the non-selected word line WLusel.

When the (N+1)-th read operation ends and the (N+1)-th read operation is not the final read operation executed in response to a command, the internal voltage VI4 generated by the boosting circuit 174 is output, as it is, in the boosting circuit 174. Conversely, when the (N+1)-th read operation is the final read operation executed in response to a command, the internal voltage VI4 (that is, the read pass voltage VREAD) generated by the boosting circuit 174 is dropped to the initial voltage.

Hereinafter, a read operation according to a comparative example will be described to compare the first embodiment to the comparative example.

FIG. 18 is a diagram illustrating the internal voltage VI4 and the read pass voltage VREAD in the read operation according to the comparative example. In the comparative example, after the N-th read operation ends, the internal voltage VI4 (that is, the read pass voltage VREAD) generated by the boosting circuit 174 is dropped to the initial voltage (for example, the power voltage VDD). Thereafter, in the (N+1)-th read operation, the internal voltage VI4 of the boosting circuit 174 is boosted to the read pass voltage VREAD and is used in the read operation. Therefore, in the comparative example, the internal voltage VI4 is dropped from the read pass voltage VREAD to the initial voltage. Thereafter, a time is required to boost the internal voltage from the initial voltage to the read pass voltage VREAD.

In the read operation according to the first embodiment, however, the internal voltage VI4 (that is, the read pass voltage VREAD) generated by the boosting circuit 174 at the time of ending of the N-th read operation is used in the (N+1)-th read operation. That is, the internal voltage VI4 of the boosting circuit 174 is supplied as the read pass voltage VREAD to the non-selected word line WLusel without a recovery and boosting in the N-th and (N+1)-th read operations.

The internal voltage VI4 used in the N-th read operation is used in the (N+1)-th read operation without a recovery and boosting. Therefore, it is possible to shorten a time between the N-th read operation and the (N+1)-th read operation. That is, it is possible to shorten a time from end of the N-th read operation to start of the (N+1)-th read operation.

The read pass voltage VREAD and the internal voltage VI4 of the boosting circuit 174 are described above, but an embodiment is not limited thereto. The same applies to other voltages and internal voltages of the boosting circuits corresponding to the other voltages used in the read operation. When the internal voltages at the time of ending of the N-th read operation are held and the internal voltages are used in the (N+1)-th read operation, it is possible to shorten a time from end of the N-th read operation to start of the (N+1)-th read operation.

### 1.5 Case in Which Erase Operation Is Consecutively Executed

An operation in a case where the erase operation is consecutively executed will be described.

### 1.5.1 First Example

In a first example, before a command related to an erase operation is transmitted from the memory controller 20 to the semiconductor memory device 10, a command to give an instruction for the voltage suspension mode is transmitted from the memory controller 20 to the semiconductor memory device 10. Accordingly, the semiconductor memory device 10 is set to the voltage suspension mode.

When the semiconductor memory device 10 is set to the voltage suspension mode, the voltage generation circuit 17A of the semiconductor memory device 10 generates and outputs the internal voltages generated during the erase operation, as they are, despite end of one erase operation until consecutive erasing operations instructed with the command end. Thereafter, after the consecutive erase operations end, the voltage suspension mode of the semiconductor memory device 10 is terminated and the voltage generation circuit 17A drops the internal voltages to the initial voltage.

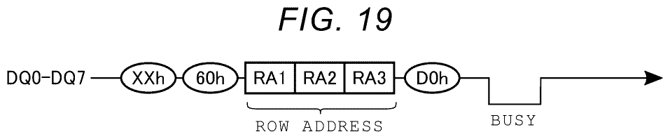

FIG. 19 is a diagram illustrating the first example of a command sequence in an erase operation according to the first embodiment.

Before a command related to the erase operation is transmitted from the memory controller 20 to the semiconductor memory device 10, the prefix command “XXh” determined in advance is transmitted. The prefix command “XXh” is a command to give an instruction for the voltage suspension mode and is a command to instruct the voltage generation circuit 17A to generate (or output) the internal voltages generated (or output) during the erase operation as they are despite end of one erase operation until end of the consecutive erase operations by a subsequently transmitted command. In the prefix command “XXh”, X indicates a hexadecimal numeral value determined in advance and h indicates that XX is hexadecimal. In other commands, the same applies to X and h.

As illustrated in FIG. 19, the memory controller 20 first transmits the prefix command “XXh” to the semiconductor memory device 10 using signals DQ0 to DQ7. The prefix command “XXh” is a command to give an instruction for the voltage suspension mode to the semiconductor memory device 10.

When the prefix command “XXh” is received, the sequencer 16 of the semiconductor memory device 10 holds the internal voltages output from the voltage generation circuit 17A, as they are, based on the prefix command “XXh” from end of the first erase operation to start of the subsequent second erase operation. That is, the internal voltages output from the voltage generation circuit 17A are held, as they are, for a predetermined period from the end of the first erase operation to the start of the second erase operation.

Subsequently, the memory controller 20 transmits a command “60h” to the semiconductor memory device 10 using the signals DQ0 to DQ7. The command “60h” is a command for notifying an input of addresses and the erase operation.

Subsequently, the memory controller 20 transmits addresses “RA1, RA2, and RA3” to the semiconductor memory device 10 in order using the signals DQ0 to DQ7. The addresses “RA1, RA2, and RA3” are addresses for designating a block of an erase target in the memory cell array 11. Here, the addresses are indicated with three cycles, but any number of cycles may be used.

Subsequently, the memory controller 20 transmits the command “D0h” to the semiconductor memory device 10 using the signals DQ0 to DQ7. The command “D0h” is a command for giving an instruction to start the erase operation on a block designated with the address. When the command “D0h” is received, the sequencer 16 starts the erase operation on the block designated with the address.

### 1.5.2 Second Example

In a second example, the semiconductor memory device 10 is set to the voltage suspension mode using a “Set Feature” command before a command related to the erase operation is transmitted from the memory controller 20 to the semiconductor memory device 10. When the semiconductor memory device 10 is set to the voltage suspension mode with the “Set Feature” command, the voltage generation circuit 17A of the semiconductor memory device 10 generates and outputs the internal voltages generated in the erase operation, as they are, despite end of the erase operation. Thereafter, after the consecutive erase operations end, the “Set Feature” command is used again to terminate the voltage suspension mode of the semiconductor memory device 10.

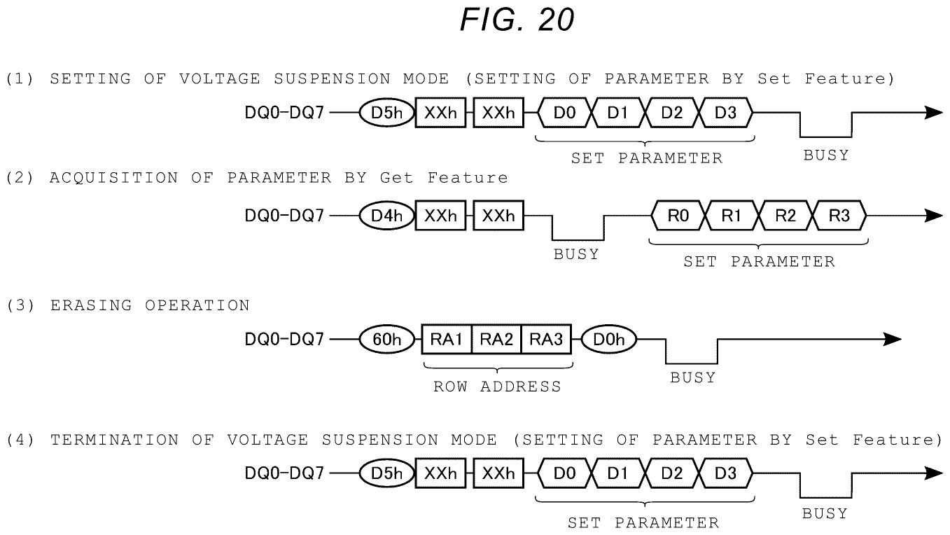

FIG. 20 is a diagram illustrating the second example of the command sequence in the erase operation according to the first embodiment.

Commands, addresses, and data shown in (1), (2), (3), and (4) in FIG. 20 are transmitted from the memory controller 20 to the semiconductor memory device 10.

First, (1) setting of a parameter with a “Set Feature” command is executed to set the semiconductor memory device 10 to the voltage suspension mode. Subsequently, (2) the acquisition of the parameter with the “Get Feature” command is executed. The acquisition of the parameter with the “Get Feature” command is executed to check whether the setting of the parameter is correctly executed, and is not executed in some cases. Subsequently, (3) the erase operation is executed. Thereafter, (4) setting of a parameter with the “Set Feature” command is executed to terminate the voltage suspension mode set in the semiconductor memory device 10.

Hereinafter, (1) to (4) will be described in detail.

### (1) Setting of Voltage Suspension Mode

First, the memory controller 20 transmits a command “D5h”, a LUN address “XXh”, and a feature address XXh” to the semiconductor memory device 10 using the signals DQ0 to DQ7. The command “D5h” is a command for notifying that an address and data transmitted after the command “D5h” are related to the setting of the parameter with the “Set Feature” command. The LUN address “XXh” is an address for designating a unit of a setting target with the “Set Feature” command. The feature address “XXh” is an address at which the parameter set with the “Set Feature” command is stored.

Subsequently, the memory controller 20 transmits the pieces of data “D0, D1, D2, and D3” to the semiconductor memory device 10 using the signals DQ0 to DQ7. The pieces of data “D0, D1, D2, and D3” are parameters set with the “Set Feature” command. With the parameter set, the semiconductor memory device 10 is set to the voltage suspension mode. When the semiconductor memory device 10 is set to the voltage suspension mode, the voltage generation circuit 17A of the semiconductor memory device 10 generates (or outputs) the internal voltages generated (or output) during the erase operation as they are despite end of the erase operation.

### (2) Acquisition of Parameter by Get Feature

The memory controller 20 transmits the command “D4h”, the LUN address “XXh”, and the feature address “XXh” to the semiconductor memory device 10 in order using the signals DQ0 to DQ7. The command “D4h” is a command for notifying that the address transmitted after the command “D4h” is related to the acquisition of the parameter with the “Get Feature” command. The LUN address “XXh” is an address for designating a unit of an acquisition target with the “Get Feature” command. The feature address “XXh” is an address at which a parameter acquired with the “Get Feature” command is stored. Accordingly, in the semiconductor memory device 10, the parameter set with the “Set Feature” command is read. Subsequently, the read pieces of data R0, R1, R2, and R3 are transmitted from the semiconductor memory device 10 to the memory controller 20. Accordingly, the memory controller 20 can ascertain whether the parameter set with the “Set Feature” command is correctly set, that is, the semiconductor memory device 10 is set to the voltage suspension mode.

### (3) Erase Operation

The erase operation is similar to the operation excluding the prefix command “XXh” in the first example.

First, the memory controller 20 transmits the command “60h” to the semiconductor memory device 10 using the signals DQ0 to DQ7. Subsequently, the memory controller 20 transmits the addresses “RA1, RA2, and RA3” to the semiconductor memory device 10 in order using the signals DQ0 to DQ7. Further, the memory controller 20 transmits the command “D0h” to the semiconductor memory device 10 using the signals DQ0 to DQ7. When the command “D0h” is received, the sequencer 16 starts the erase operation on blocks designated with the addresses.

### (4) Termination of Setting of Voltage Suspension Mode

The memory controller 20 transmits the command “D5h”, the LUN address “XXh”, and the feature address “XXh” to the semiconductor memory device 10 using the signals DQ0 to DQ7. The command “D5h” is a command indicating that the data and the address transmitted after the command “D5h” are related to the setting of the parameter with the “Set Feature” command. The LUN address “XXh” and the feature address “XXh” are similar to the above-described addresses.

Subsequently, the memory controller 20 transmits the pieces of data “D0, D1, D2, and D3” to the semiconductor memory device 10 using the signals DQ0 to DQ7. The pieces of data “D0, D1, D2, and D3” are parameters set with the “Set Feature” command. With the parameter set, the voltage suspension mode set in the semiconductor memory device 10 is terminate. When the setting of the voltage suspension mode is terminated and the erase operation ends, the voltage generation circuit 17A of the semiconductor memory device 10 drops the internal voltages generated during the erase operation to the initial voltage.

As described above, the setting and the termination of the voltage suspension mode in the erase operation are executed using the “Set Feature” command.

### 1.5.3 Erase Operation in First and Second Examples

An erase operation executed in the above-described first and second examples on the memory cell transistors will be described.

As described above, in the erase operation, the internal voltage VI5 output from the boosting circuit 175 of the voltage generation circuit 17A is supplied as an erase voltage VERA to a source line SL of a selected block of the erase target via the driver 17B. Here, the internal voltage VI5 output from the boosting circuit 175 and the erase voltage VERA supplied to the source line SL of the selected block will be described as examples.

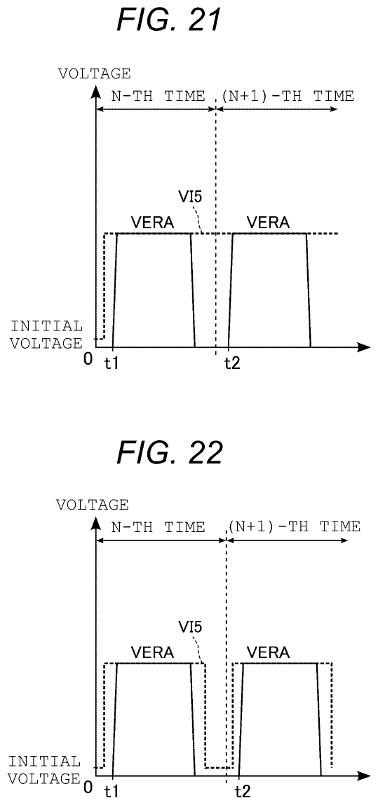

FIG. 21 is a diagram illustrating the internal voltage VI5 and the erase voltage VERA in the erase operation according to the first embodiment. In FIG. 21, the erase voltage VERA is indicated by a solid line and the internal voltage VI5 is indicated by a dotted line.

The erase operation is executed for each block on a plurality of blocks in the memory cell array 11. As N-th and (N+1)-th erase operations illustrated in FIG. 21, two erase operations are extracted from the erase operations executed for each block. In the N-th erase operation, the internal voltage VI5 output from the boosting circuit 175 is supplied as the erase voltage VERA to the source line SL of the selected block. In the (N+1)-th erase operation, the internal voltage VI5 is supplied as the erase voltage VERA to the source line SL of the subsequent selected block.

The N-th erase operation is executed as follows.

As illustrated in FIG. 21, at time t1, the erase operation is executed on the memory cell transistor of the selected block using the erase voltage VERA. In the erase operation, the internal voltage VI5 is output from the boosting circuit 175 of the voltage generation circuit 17A, and the internal voltage VI5 is supplied as the erase voltage VERA to the source line SL of the selected block of the erase target.

When the N-th erase operation ends, the internal voltage VI5 (that is, the erase voltage VERA) generated by the boosting circuit 175 at the time of ending of the N-th erase operation is generated and output, as it is, in the boosting circuit 175 until the (N+1)-th erase operation starts.

Subsequently, the (N+1)-th erase operation is executed as follows.

At time t2, the erase operation is executed on the memory cell transistor of the subsequent selected block using the erase voltage VERA. In the erase operation, the internal voltage VI5 (that is, the erase voltage VERA) generated by the boosting circuit 175 when the N-th erase operation ends is supplied as the erase voltage VERA to the source line SL of the selected block.

When the (N+1)-th erase operation ends and the (N+1)-th erase operation is not the final erase operation executed in response to a command, the internal voltage VI5 is generated and output, as it is, in the boosting circuit 175. Conversely, when the (N+1)-th erase operation is the final erase operation executed in response to a command, the internal voltage VI5 generated by the boosting circuit 175 is dropped to the initial voltage.

Hereinafter, an erase operation according to a comparative example will be described to compare the first embodiment to the comparative example.

FIG. 22 is a diagram illustrating the internal voltage VI5 and the erase voltage VERA in the erase operation according to the comparative example. In the comparative example, after the N-th erase operation ends, the internal voltage VI5 (that is, the erase voltage VERA) generated by the boosting circuit 175 is dropped to the initial voltage (for example, the power voltage VDD). Thereafter, in the (N+1)-th erase operation, the internal voltage VI5 of the boosting circuit 175 is boosted to the erase voltage VERA and is used in the erase operation. Therefore, in the comparative example, the internal voltage VI5 is dropped from the erase voltage VERA to the initial voltage. Thereafter, a time is required to boost the internal voltage from the initial voltage to the erase voltage VERA.

In the erase operation according to the first embodiment, however, the internal voltage VI5 (that is, the voltage VERA) generated by the boosting circuit 175 at the time of ending of the N-th erase operation is used in the (N+1)-th erase operation. That is, the internal voltage VI5 of the boosting circuit 175 is supplied as the erase voltage VERA to the source line SL of the selected block without a recovery and boosting in the N-th and (N+1)-th erase operations.

The internal voltage VI5 used in the N-th erase operation is used in the (N+1)-th erase operation without a recovery and boosting. Therefore, it is possible to shorten a time between the N-th erase operation and the (N+1)-th erase operation. That is, it is possible to shorten a time from end of the N-th erase operation to start of the (N+1)-th erase operation.

The erase voltage VERA and the internal voltage VI5 of the boosting circuit 175 are described above, but an embodiment is not limited thereto. The same applies to other voltages and internal voltages of the boosting circuits corresponding to the other voltages used in the erase operation. When the internal voltages at the time of ending of the N-th erase operation are held and the internal voltages are used in the (N+1)-th erase operation, it is possible to shorten a time from end of the N-th erase operation and start of the (N+1)-th erase operation.

### 1.6 Advantages and Like of First Embodiment

The semiconductor memory device and the memory system according to the first embodiment can shorten a time between operations in consecutive write operations (or consecutive read operations or consecutive erase operations).

In the semiconductor memory device according to the first embodiment, in the consecutive write operations (or consecutive read operations or consecutive erase operations), the internal voltages are held until the second operation (or a subsequent operation) starts without executing a recovery of the internal voltages of the voltage generation circuit 17A after end of the first operation (or a previous operation). That is, after the first operation ends, voltage levels of the internal voltages are held until the second operation starts. Then, the internal voltages held after end of the first operation remain or are set as operation voltages, and are used as operation voltages in the second operation. Accordingly, it is possible to shorten a time from end of the first operation to start of the second operation. When a period from the first operation to the second operation is short, it is possible to reduce power consumption occurring in a case where the first and second operations are consecutively executed.

In the memory system according to the first embodiment, by transmitting the prefix command “XXh” or the “Set Feature” command set in advance from the memory controller 20 to the semiconductor memory device 10, it is possible to notify the semiconductor memory device 10 that the internal voltages generated by the voltage generation circuit 17A are held after each operation of the consecutive write operations (or the consecutive read operation or the consecutive erase operations) ends.

When the prefix command “XXh” or the “Set Feature” command is received, the semiconductor memory device 10 holds the internal voltages until the second operation starts without executing the recovery of the internal voltages generated by the voltage generation circuit 17A even after end of the first operation in the consecutive write operations (or the consecutive read operation or the consecutive erase operations). That is, after the first operation ends, the voltage levels of the internal voltages are held until start of the second operation. The internal voltages held after the end of the first operation remain or are set to operation voltages, and are used as operation voltages in the second operation. Accordingly, it is possible to shorten a time from end of the first operation to start of the second operation. When a period from the first operation to the second operation is short, it is possible to reduce power consumption occurring in a case where the first and second operations are consecutively executed.

### 2. Second Embodiment

A memory system according to a second embodiment will be described. In the second embodiment, an operation in a case where an erase operation, a write operation, and a read operation are consecutively executed will be described below. In the second embodiment, differences from those of the first embodiment will be mainly described.

### 2.1 Configuration of Memory System

Circuit configurations of the memory controller 20 and the semiconductor memory device 10 according to the second embodiment are similar to those of the first embodiment.

### 2.2 Operation of Memory System

An operation of the memory system 1 according to the second embodiment will be described. Hereinafter, an operation in a case where an erase operation, a write operation, a read operation, and an erase operation are consecutively executed will be described below.

### 2.2.1 First Example

In a first example, before a command related to each of an erase operation, a write operation, and a read operation is transmitted from the memory controller 20 to the semiconductor memory device 10, a command to give an instruction for the voltage suspension mode is transmitted from the memory controller 20 to the semiconductor memory device 10. Accordingly, the semiconductor memory device 10 is set to the voltage suspension mode in each operation of the erase operation, the write operation, and the read operation.

If the semiconductor memory device 10 is set to the voltage suspension mode, the voltage generation circuit 17A of the semiconductor memory device 10 generates and outputs the internal voltages generated during an operation despite of end of the erase operation, the write operation, and the read operation instructed with the command. Thereafter, when the consecutive operations end, the voltage suspension mode of the semiconductor memory device 10 is terminated and the voltage generation circuit 17A drops the internal voltages to the initial voltage after elapse of a certain time.

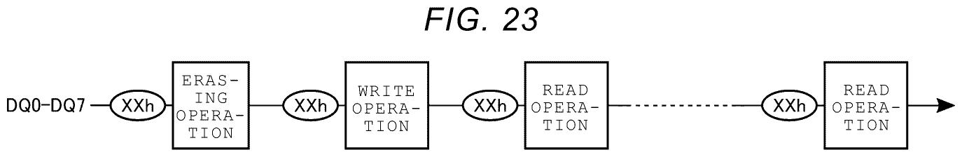

FIG. 23 is a diagram illustrating a first example of a command sequence in an erase operation, a write operation, and a read operation according to the second embodiment.

For example, before a command related to the erase operation is transmitted from the memory controller 20 to the semiconductor memory device 10, the prefix command “XXh” determined in advance is transmitted. The prefix command “XXh” is a command to give an instruction for the voltage suspension mode and is a command to instruct the voltage generation circuit 17A to generate (or output) the internal voltages generated (or output) during the erase operation, as they are, despite of end of the erase operation with a subsequently transmitted command. Subsequently, the memory controller 20 transmits the command related to the erase operation to the semiconductor memory device 10 using the signals DQ0 to DQ7. The above-described prefix command “XXh” and the command related to the erase operation are similar to those illustrated in FIG. 19.

Before a command related to the write operation is transmitted from the memory controller 20 to the semiconductor memory device 10, the prefix command “XXh” determined in advance is transmitted. The prefix command “XXh” is a command to give an instruction for the voltage suspension mode and is a command to instruct the voltage generation circuit 17A to generate (or output) the internal voltages generated (or output) during the write operation, as they are, despite end of the write operation with the subsequently transmitted command. Subsequently, the memory controller 20 transmits the command related to the write operation to the semiconductor memory device 10 using the signals DQ0 to DQ7. The above-described prefix command “XXh” and the command related to the write operation are similar to those illustrated in FIG. 11.

Before a command related to the read operation is transmitted from the memory controller 20 to the semiconductor memory device 10, the prefix command “XXh” determined in advance is transmitted. The prefix command “XXh” is a command to give an instruction for the voltage suspension mode and is a command to instruct the voltage generation circuit 17A to generate (or output) the internal voltages generated (or output) during the read operation, as they are, despite end of the read operation with the subsequently transmitted command. Subsequently, the memory controller 20 transmits the command related to the read operation to the semiconductor memory device 10 using the signals DQ0 to DQ7. The above-described prefix command “XXh” and the command related to the read operation are similar to those illustrated in FIG. 15.

As described above, by transmitting each of the prefix command “XXh” and the command related to the erase operation, the prefix command “XXh” and the command related to the write operation, and the prefix command “XXh” and the command related to the read operation, it is possible to consecutively execute the erase operation, the write operation, and the read operation.

Thereafter, by transmitting the prefix command “XXh” and the command related to each operation, it is also possible to consecutively execute each operation.

### 2.2.2 Second Example

In a second example, the semiconductor memory device 10 is set to the voltage suspension mode using a “Set Feature” command before a command related to the erase, write, and read operations is transmitted from the memory controller 20 to the semiconductor memory device 10. When the semiconductor memory device 10 is set to the voltage suspension mode with the “Set Feature” command, the voltage generation circuit 17A of the semiconductor memory device 10 generates and outputs the internal voltages generated in each operation, as they are, despite end of each of the erase, write, and read operations. Thereafter, after the consecutive erase, write, and read operations end, the “Set Feature” command is used again to terminate the voltage suspension mode of the semiconductor memory device 10.

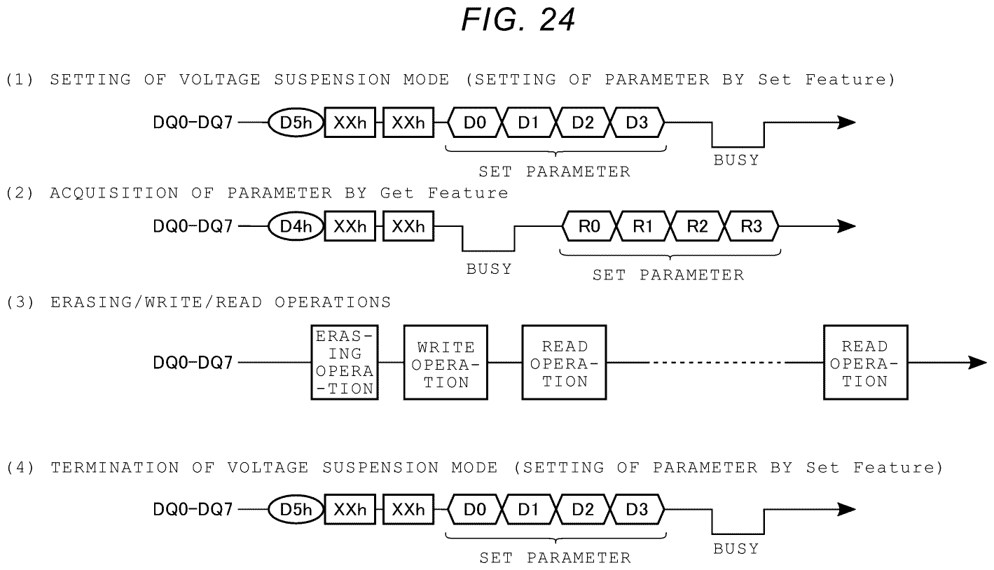

FIG. 24 is a diagram illustrating a second example of the command sequence in the erase operation, the write operation, and the read operation according to the second embodiment.

Commands, addresses, and data shown in (1), (2), (3), and (4) in FIG. 24 are transmitted from the memory controller 20 to the semiconductor memory device 10.

First, (1) setting of a parameter with a “Set Feature” command is executed to set the semiconductor memory device 10 to the voltage suspension mode. Subsequently, (2) the acquisition of the parameter with the “Get Feature” command is executed. The acquisition of the parameter with the “Get Feature” command is executed to check whether the setting of the parameter is correctly executed, and is not executed in some cases. Subsequently, (3) the erase operation is executed. Thereafter, (4) setting of a parameter with the “Set Feature” command is executed to terminate the voltage suspension mode set in the semiconductor memory device 10.

Hereinafter, (1) to (4) will be described in detail.

### (1) Setting of Voltage Suspension Mode

First, the memory controller 20 transmits the command “D5h”, the LUN address “XXh”, and the feature address XXh” to the semiconductor memory device 10 using the signals DQ0 to DQ7. The command “D5h” is a command for notifying that an address and data transmitted after the command “D5h” are related to the setting with the “Set Feature” command. The LUN address “XXh” is an address for designating a unit of a setting target with the “Set Feature” command. The feature address “XXh” is an address at which the parameter set with the “Set Feature” command is stored.

Subsequently, the memory controller 20 transmits the pieces of data “D0, D1, D2, and D3” to the semiconductor memory device 10 using the signals DQ0 to DQ7. The pieces of data “D0, D1, D2, and D3” are parameters set with the “Set Feature” command. With the parameter set, the semiconductor memory device 10 is set to the voltage suspension mode. When the semiconductor memory device 10 is set to the voltage suspension mode, the voltage generation circuit 17A of the semiconductor memory device 10 generates (or outputs) the internal voltages generated (or output) during each operation despite end of the erase, write, and read operations.

### (2) Acquisition of Parameter by Get Feature

The memory controller 20 transmits the command “D4h”, the LUN address “XXh”, and the feature address “XXh” to the semiconductor memory device 10 using the signals DQ0 to DQ7. The command “D4h” is a command for notifying that the address transmitted after the command “D4h” is related to the acquisition of the parameter with the “Get Feature” command. The LUN address “XXh” is an address for designating a unit of an acquisition target with the “Get Feature” command. The feature address “XXh” is an address at which a parameter acquired with the “Get Feature” command is stored. Accordingly, in the semiconductor memory device 10, the parameter set with the “Set Feature” command is read. Subsequently, the read pieces of data R0, R1, R2, and R3 are transmitted from the semiconductor memory device 10 to the memory controller 20. Accordingly, the memory controller 20 can ascertain whether the parameter set with the “Set Feature” command is correctly set, that is, the semiconductor memory device 10 is set to the voltage suspension mode.

### (3) Erase Operation, Write Operation, and Read Operation

The erase operation, the write operation, and the read operation are similar to the operation excluding the prefix command “XXh” in the first example.

### (4) Termination of Setting of Voltage Suspension Mode

The memory controller 20 transmits the command “D5h”, the LUN address “XXh”, and the feature address “XXh” to the semiconductor memory device 10 in order using the signals DQ0 to DQ7. The command “D5h” indicates that the data and the address transmitted after the command “D5h” are related to the setting of the parameter with the “Set Feature” command. The LUN address “XXh” and the feature address “XXh” are similar to the above-described addresses.

Subsequently, the memory controller 20 transmits the pieces of data “D0, D1, D2, and D3” to the semiconductor memory device 10 using the signals DQ0 to DQ7. The pieces of data “D0, D1, D2, and D3” are parameters set with the “Set Feature” command. With the parameter set, the voltage suspension mode set in the semiconductor memory device 10 is terminated. When the setting of the voltage suspension mode is terminated and the consecutive erase, write, and read operations end, the voltage generation circuit 17A of the semiconductor memory device 10 drops the internal voltages generated during each operation to the initial voltage.

As described above, the setting and the termination of the voltage suspension mode in the consecutive erase, write, and read operations are executed using the “Set Feature” command.

### 2.2.3 Erase Operation, Write Operation, and Read Operation in First and Second Examples

An erase operation, a write operation, and a read operation executed in the above-described first and second examples on the memory cell transistors will be described.

Here, it is assumed, for example, that the internal voltage VI5 output from the boosting circuit 175 of the voltage generation circuit 17A is supplied as the erase voltage VERA in the erase operation, is supplied as the write voltage VPGM in the write operation, and is supplied as the read pass voltage VREAD in the read operation. That is, the internal voltage VI5 generated by one boosting circuit 175 is supplied as the erase voltage VERA, the write voltage VPGM, or the read pass voltage VREAD.

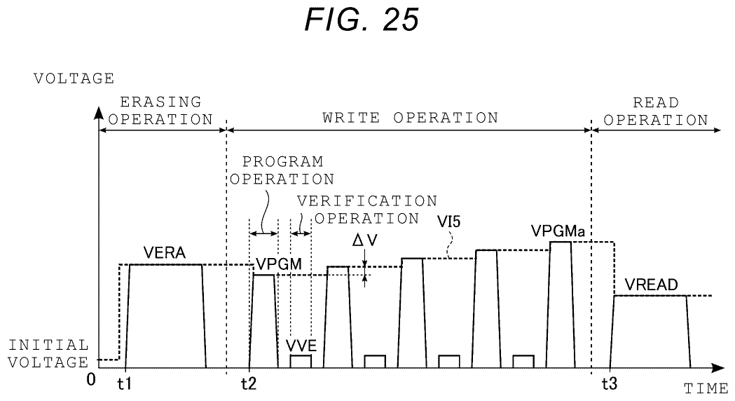

FIG. 25 is a diagram illustrating an internal voltage, an erase voltage, a write voltage, and a read pass voltage in the erase operation, the write operation, and the read operation according to the second embodiment. In FIG. 25, the erase voltage VERA, the write voltage VPGM, and the read pass voltage VREAD are indicated by solid lines and the internal voltage VI5 is indicated by a dotted line.

For example, it is assumed that the semiconductor memory device 10 is not set to the voltage suspension mode before the erase operation illustrated in FIG. 25 and the semiconductor memory device 10 is set to the voltage suspension mode from end of an operation before the erase operation to start of the erase operation. Therefore, before the erase operation starts, the internal voltage VI5 output from the boosting circuit 175 of the voltage generation circuit 17A is set to the initial voltage.

As illustrated in FIG. 25, when the erase operation starts, the internal voltage VI5 output from the boosting circuit 175 is boosted from the initial voltage to the erase voltage VERA. At time t1, the erase operation is executed on the memory cell transistor of the selected block using the erase voltage VERA. In the erase operation, the internal voltage VI5 is output from the boosting circuit 175 of the voltage generation circuit 17A, and the internal voltage VI5 is supplied as the erase voltage VERA to the source line SL of the selected block of the erasing target.

When erase operation ends, the internal voltage VI5 (that is, the erase voltage VERA) generated by the boosting circuit 175 at the time of ending of the erase operation is generated and output, as it is, in the boosting circuit 175 until a subsequent operation (for example, the write operation) starts.

Subsequently, at time t2, the program operation is executed on the memory cell transistor using the write voltage VPGM. In the program operation, the internal voltage VI5 generated by the boosting circuit 175 when the erase operation ends is set to the write voltage VPGM and is supplied to the selected word line WLsel.

Subsequently, the program verification operation is executed on the memory cell transistor using the verification voltage VVE. When the verification by the program verification operation fails, the write voltage VPGM increases by the given voltage LV, the program operation is executed again, and the program verification operation is executed. The program operation and the program verification operation are repeatedly executed until the verification by the program verification operation passes.

When the verification by the program verification operation passes, the write operation ends. When the write operation ends, the internal voltage VI5 (that is, the write voltage VPGMa) generated by the boosting circuit 175 when the write operation ends is generated and output, as it is, in the boosting circuit 175 until a subsequent operation (for example, the read operation) starts.

Subsequently, at time t3, the read operation is executed on the memory cell transistor using the read voltage VCGRV (not illustrated) and the read pass voltage VREAD. In the read operation, the internal voltage VI5 (that is, the write voltage VPGMa) generated by the boosting circuit 175 when the write operation ends is set to the read pass voltage VREAD and supplied to the non-selected word line WLusel.

When the read operation ends, the internal voltage VI5 (that is, the read pass voltage VREAD) generated by the boosting circuit 175 when the read operation ends is generated and output, as it is, by the boosting circuit 175 until a subsequent operation starts.

### 2.3 Advantages and Like of Second Embodiment

The semiconductor memory device and the memory system according to the second embodiment can shorten a time between operations in consecutive erase, write, and read operations.

In the semiconductor memory device according to the second embodiment, in the consecutive erase, write, and read operations, the internal voltages are held until the second operation (or a subsequent operation) starts without executing a recovery of the internal voltages of the voltage generation circuit 17A after end of the first operation (or a previous operation). That is, after the first operation ends, voltage levels of the internal voltages are held until the second operation starts. Then, the internal voltages held after end of the first operation remain or are set as operation voltages, and are used as operation voltages in the second operation. Accordingly, it is possible to shorten a time from end of the first operation to start of the second operation. When a period from the first operation to the second operation is short, it is possible to reduce power consumption occurring in a case where the first and second operations are consecutively executed.

In the memory system according to the second embodiment, by transmitting the prefix command “XXh” or the “Set Feature” command set in advance from the memory controller 20 to the semiconductor memory device 10, it is possible to notify the semiconductor memory device 10 that the internal voltages generated by the voltage generation circuit 17A are held after each operation of the consecutive erase, write, and erase operations ends.

When the prefix command “XXh” or the “Set Feature” command is received, the semiconductor memory device 10 holds the internal voltages until the second operation starts without executing the recovery of the internal voltages generated by the voltage generation circuit 17A even after end of the first operation in the consecutive erase, write, and erase operations. That is, after the first operation ends, the voltage levels of the internal voltages are held until start of the second operation. The internal voltages held after the end of the first operation remain or are set to operation voltages, and are used as operation voltages in the second operation. Accordingly, it is possible to shorten a time from end of the first operation to start of the second operation. When a period from the first operation to the second operation is short, it is possible to reduce power consumption occurring in a case where the first and second operations are consecutively executed.

### 3. Others

Further, as described above, the NAND flash memory is described as an example of the semiconductor memory device. An embodiment is not limited to the NAND flash memory and can be applied to any of other semiconductor memory devices and can be further applied to various memory devices other than the semiconductor memory device.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a memory cell array;
a control circuit configured to perform a first operation to access the memory cell array and then a second operation to access the memory cell array; and
a voltage generation circuit configured to generate a first operation voltage, which is supplied to from an output terminal of the voltage generation circuit to the memory cell array during the first operation, and a second operation voltage, which is supplied from the output terminal to the memory cell array during the second operation, wherein
the control circuit is configured to control the voltage generation circuit to maintain a voltage output from the output terminal to be at the first operation voltage after the first operation until the second operation voltage starts to be supplied to the memory cell array for the second operation.

2. The semiconductor memory device according to claim 1, wherein
the first operation is one of a write operation, a read operation, and an erase operation, and
the second operation is the same one of the write operation, the read operation, and the erase operation.

3. The semiconductor memory device according to claim 1, wherein
the memory cell array includes a first memory cell and a word line connected to the first memory cell,
the first operation is a write operation with respect to the first memory cell, and the first operation voltage is supplied from the output terminal to the word line during the first operation, and
the second operation is a write operation with respect to the first memory cell, and the second operation voltage is supplied from the output terminal to the word line during the second operation.

4. The semiconductor memory device according to claim 3, wherein the first operation voltage is a first program voltage and the second operation voltage is a second program voltage different from the first program voltage.

5. The semiconductor memory device according to claim 1, wherein
the memory cell array includes a first memory cell and a word line connected to the first memory cell,
the first operation is a read operation with respect to a memory cell other than the first memory cell, and the first operation voltage is supplied from the output terminal to the word line during the first operation, and
the second operation is a read operation with respect to a memory cell other than the first memory cell, and the second operation voltage is supplied from the output terminal to the word line during the second operation.

6. The semiconductor memory device according to claim 5, wherein the first operation voltage is a read pass voltage, and the second operation voltage is equal to the first operation voltage.

7. The semiconductor memory device according to claim 1, wherein
the memory cell array includes a first memory cell, a second memory cell, a first source line connected to the first memory cell, and a second source line connected to the second memory cell,
the first operation is an erase operation with respect to the first memory cell, and the first operation voltage is supplied from the output terminal to the first source line during the first operation, and
the second operation is a read operation with respect to the second memory cell, and the second operation voltage is supplied from the output terminal to the second source line during the second operation.

8. The semiconductor memory device according to claim 7, wherein the first operation voltage is an erase voltage, and the second operation voltage is equal to the first operation voltage.

9. The semiconductor memory device according to claim 1, wherein
the first operation is one of a write operation, a read operation, and an erase operation, and
the second operation is another one of the write operation, the read operation, and the erase operation.

10. The semiconductor memory device according to claim 1, wherein
the memory cell array includes a first memory cell, a word line connected to the first memory cell, and a source line connected to the first memory cell,
the first operation is an erase operation with respect to the first memory cell, and the first operation voltage is supplied from the output terminal to the source line during the first operation, and
the second operation is a write operation with respect to the first memory cell, and the second operation voltage is supplied from the output terminal to the word line during the second operation.

11. The semiconductor memory device according to claim 1, wherein
the memory cell array includes a first memory cell and a word line connected to the first memory cell,
the first operation is an erase operation with respect to the first memory cell, and the first operation voltage is supplied from the output terminal to the source line during the first operation, and
the second operation is a write operation with respect to a memory cell other than the first memory cell, and the second operation voltage is supplied from the output terminal to the word line during the second operation.

12. The semiconductor memory device according to claim 1, wherein
the control circuit is configured to perform a third operation to access the memory cell array after the second operation,
the voltage generation circuit is configured to generate a third operation voltage, which is supplied to from the output terminal of the voltage generation circuit to the memory cell array during the third, and
the control circuit is configured to control the voltage generation circuit to maintain the voltage output from the output terminal to be at the second operation voltage after the second operation until the third operation voltage starts to be supplied to the memory cell array for the third operation.

13. The semiconductor memory device according to claim 12, wherein
the first operation is one of a write operation, a read operation, and an erase operation, and
the second operation is another one of the write operation, the read operation, and the erase operation, and
the third operation is still another one of the write operation, the read operation, and the erase operation.

14. The semiconductor memory device according to claim 1, wherein
the semiconductor memory device is configured to operate in a first mode and a second mode,
in the first mode, the control circuit is configured to control the voltage generation circuit to maintain the voltage output from the output terminal to be at the first operation voltage after the first operation until the second operation voltage starts to be supplied to the memory cell array for the second operation, and
in the second mode, the control circuit is configured to control the voltage generation circuit to cause the voltage output from the output terminal to drop from the first operation voltage after the first operation and before the second operation voltage starts to be supplied to the memory cell array for the second operation.

15. The semiconductor memory device according to claim 14, wherein the control circuit is configured to switch an operational mode of the semiconductor memory device to the first mode in response to a first command input from outside of the semiconductor memory device.

16. The semiconductor memory device according to claim 15, wherein the control circuit is configured to switch the operational mode of the semiconductor memory device to the first mode and then perform the first operation, in response to a set of commands including the first command followed by a second command instructing the first operation.

17. The semiconductor memory device according to claim 15, wherein the control circuit is configured to perform the first operation in response to a second command received separately from the first command, from the outside of the semiconductor memory device in the first mode.

18. A memory system comprising:
the semiconductor memory device according to claim 1; and
a memory controller connectable to a host and configured to control the semiconductor memory device in accordance with a command from the host.
